(19) United States
(12) Patent Application Publication
(10) Pub. No.: US 2026/0010201 A1
(43) Pub. Date: Jan. 8, 2026

(54) WEARABLE ELECTRONIC DEVICE FOR EXECUTING FUNCTION, OPERATION METHOD THEREOF, AND STORAGE MEDIUM

(71) Applicant: SAMSUNG ELECTRONICS CO., LTD., Suwon-si (KR)

(72) Inventors: Jinyung JUNG, Suwon-si (KR); Nina Lee, Suwon-si (KR); Seungyong Lee, Suwon-si (KR); Yeunwook Lim, suwon-si (KR); Junsu Hwang, Suwon-si (KR)

(73) Assignee: SAMSUNG ELECTRONICS CO., LTD., Suwon-si (KR)

(21) Appl. No.: 19/259,915

(22) Filed: Jul. 3, 2025

Related U.S. Application Data
(63) Continuation of application No. PCT/KR2025/009321, filed on Jul. 1, 2025.

(30) Foreign Application Priority Data
Jul. 4, 2024 (KR) 10-2024-0088341
Aug. 28, 2024 (KR) 10-2024-0115551

(51) Int. Cl. G06F 1/16; G01R 31/382

(52) U.S. Cl. CPC G06F 1/163; G01R 31/382

(57) ABSTRACT

A wearable device is provided. The wearable device according to the disclosure, based on receiving, through the communication circuitry, a message requesting information for executing the second function, provide information related to the first function to the first external electronic device so that the first external electronic device executes the second function using the information related to the first function.

### CROSS-REFERENCE TO RELATED APPLICATIONS

This application is a continuation of International Application No. PCT/KR2025/009321 designating the United States, filed on Jul. 1, 2025, in the Korean Intellectual Property Receiving Office and claiming priority to Korean Patent Application No. 10-2024-0088341, filed on Jul. 4, 2024, and Korean Patent Application No. 10-2024-0115551, filed on Aug. 28, 2024 in the Korean Intellectual Property Office, the disclosures of each of which are incorporated by reference herein in their entireties.

### TECHNICAL FIELD

Various embodiments relate to a wearable electronic device for executing a function, an operation method thereof, and a storage medium.

### BACKGROUND ART

Advancing information communication and semiconductor technologies accelerate the spread and use of various electronic devices. Electronic devices are being developed to carry out communication while carried on by the user. Electronic device may mean a device that performs specific functions according to an installed program, such as mobile communication terminals, tablet PCs, wearable electronic devices, video/audio devices, desktop/laptop computers, or vehicle navigation devices. Here, wearable electronic device may mean an electronic device that may be worn on the body. While smartphones and tablet PCs require users to hold them in their hands, wearable electronic devices may be worn on the body, making them more portable than smartphones or tablet PCs.

The above-described information may be provided as related art for the purpose of helping understanding of the disclosure. No claim or determination is made as to whether any of the foregoing is applicable as background art in relation to the disclosure.

### SUMMARY

According to an embodiment, a wearable electronic device may comprise a sensor, communication circuitry, at least one processor, and memory storing instructions.

According to an embodiment, the instructions may be configured to, when executed by the at least one processor individually or collectively, cause the wearable electronic device to execute a first function of the wearable electronic device.

According to an embodiment, the instructions may be configured to, when executed by the at least one processor individually or collectively, cause the wearable electronic device to determine, through the sensor, that the wearable electronic device is not worn on a user's body while executing the first function.

According to an embodiment, the instructions may be configured to, when executed by the at least one processor individually or collectively, cause the wearable electronic device to identify, through the communication circuitry, at least one external electronic device around the wearable electronic device.

According to an embodiment, the instructions may be configured to, when executed by the at least one processor individually or collectively, cause the wearable electronic device to based on identifying a first external electronic device, which satisfies a specified condition, among the at least one external electronic device, cause the first external electronic device to display information indicating that a second function, corresponding to the first function, of the first external electronic device is executable on the first external electronic device.

According to an embodiment, the instructions may be configured to, when executed by the at least one processor individually or collectively, cause the wearable electronic device to based on receiving, through the communication circuitry, a message requesting information for executing the second function, provide information related to the first function to the first external electronic device so that the first external electronic device executes the second function using the information related to the first function.

According to an embodiment, a method for operating a wearable electronic device may comprise executing a first function of the wearable electronic device.

According to an embodiment, the method for operating the wearable electronic device may comprise determining, through a sensor included in the wearable electronic device, that the wearable electronic device is not worn on a user's body while executing the first function.

According to an embodiment, the method for operating the wearable electronic device may comprise identifying, through communication circuitry included in the wearable electronic device, at least one external electronic device around the wearable electronic device.

According to an embodiment, the method for operating the wearable electronic device may comprise, based on identifying a first external electronic device, which satisfies a specified condition, among the at least one external electronic device, causing the first external electronic device to display information indicating that a second function, corresponding to the first function, of the first external electronic device is executable on the first external electronic device.

According to an embodiment, the method for operating the wearable electronic device may comprise, based on receiving, through the communication circuitry, a message requesting information for executing the second function, providing information related to the first function to the first external electronic device so that the first external electronic device executes the second function using the information related to the first function.

According to an embodiment, in a non-transitory storage medium storing computer-readable instructions, the instructions may, when executed by at least one processor of a wearable electronic device, cause the wearable electronic device to perform at least one operation. The at least one operation may comprise executing a first function of the wearable electronic device.

According to an embodiment, in the non-transitory storage medium storing computer-readable instructions, the instructions may, when executed by the at least one processor of the wearable electronic device, cause the wearable electronic device to perform at least one operation. The at least one operation may comprise determining, through a sensor included in the wearable electronic device, that the wearable electronic device is not worn on a user's body while executing the first function.

According to an embodiment, in the non-transitory storage medium storing computer-readable instructions, the instructions may, when executed by the at least one processor of the wearable electronic device, cause the wearable electronic device to perform at least one operation. The at least one operation may comprise identifying, through communication circuitry included in the wearable electronic device, at least one external electronic device around the wearable electronic device.

According to an embodiment, in the non-transitory storage medium storing computer-readable instructions, the instructions may, when executed by the at least one processor of the wearable electronic device, cause the wearable electronic device to perform at least one operation. The at least one operation may comprise based on identifying a first external electronic device, which satisfies a specified condition, among the at least one external electronic device, causing the first external electronic device to display information indicating that a second function, corresponding to the first function, of the first external electronic device is executable on the first external electronic device.

According to an embodiment, in the non-transitory storage medium storing computer-readable instructions, the instructions may, when executed by the at least one processor of the wearable electronic device, cause the wearable electronic device to perform at least one operation. The at least one operation may comprise, based on receiving, through the communication circuitry, a message requesting information for executing the second function from the first external electronic device, providing information related to the first function to the first external electronic device so that the first external electronic device executes the second function using the information related to the first function.

### BRIEF DESCRIPTION OF DRAWINGS

FIG. 1 is a view illustrating an electronic device in a network environment according to an embodiment;

FIG. 2A is a view illustrating a system including a wearable electronic device, a first external electronic device, a second external electronic device, and a server according to an embodiment;

FIG. 2B is a view illustrating a system including a wearable electronic device, a first external electronic device, and a second external electronic device according to an embodiment;

FIG. 3 is a view illustrating an operation of providing information related to a function being executed by the wearable electronic device to the first external electronic device according to an embodiment;

FIG. 4 is a view illustrating an operation of providing information related to a function being executed by the wearable electronic device to the first external electronic device according to an embodiment;

FIG. 5 is a flowchart illustrating an operation in which a wearable electronic device according to an embodiment identifies a device satisfying a specified condition among the at least one external electronic device;

FIG. 6 is a flowchart illustrating an operation in which a wearable electronic device according to an embodiment identifies a device satisfying a specified condition among the at least one external electronic device;

FIG. 7 is a flowchart illustrating an operation in which a wearable electronic device according to an embodiment identifies a device satisfying a specified condition among the at least one external electronic device;

FIG. 8 is a flowchart illustrating an operation in which a wearable electronic device according to an embodiment identifies whether a first external electronic device satisfying a specified condition is a device capable of executing at least one function;

FIG. 9A is a flowchart illustrating an operation in which a wearable electronic device according to an embodiment identifies a device capable of executing a function of the wearable electronic device based on history information;

FIG. 9B is a flowchart illustrating an operation of transmitting a message for displaying information about a second function and a third function as one group by a wearable electronic device according to an embodiment;

FIG. 10 is a flowchart illustrating an operation in which a wearable electronic device according to an embodiment transmits information about a first function;

FIG. 11A is a view illustrating a home screen of a wearable electronic device according to an embodiment;

FIG. 11B is a view illustrating an operation in which a wearable electronic device according to an embodiment transmits information about a plurality of functions being executed by the wearable electronic device to a first external electronic device according to an embodiment;

FIG. 12 is a view illustrating an operation in which a first external electronic device according to an embodiment displays information about devices capable of executing a function related to a timer among a plurality of functions according to an embodiment;

FIG. 13 is a view illustrating an operation of displaying information about functions executable on a first external electronic device and a second external electronic device according to an embodiment;

FIG. 14 is a view illustrating an operation in which a first external electronic device according to an embodiment displays information about functions being executed on a wearable electronic device as one group;

FIG. 15 is a view illustrating an operation in which a first external electronic device according to an embodiment displays information about functions executed at the same time on a wearable electronic device as one group;

FIG. 16A is a view illustrating a setting screen of a first external electronic device according to an embodiment;

FIG. 16B is a view illustrating an operation in which a first external electronic device according to an embodiment displays information about a device capable of executing a function being executed on a wearable electronic device;

FIG. 16C is a view illustrating an operation in which a first external electronic device according to an embodiment displays information about a function executable on a second external electronic device; and

FIG. 17 is a flowchart illustrating an operation in which a first external electronic device according to an embodiment transmits information related to a function to a second external electronic device capable of executing a function being executed on a wearable electronic device.

### DETAILED DESCRIPTION

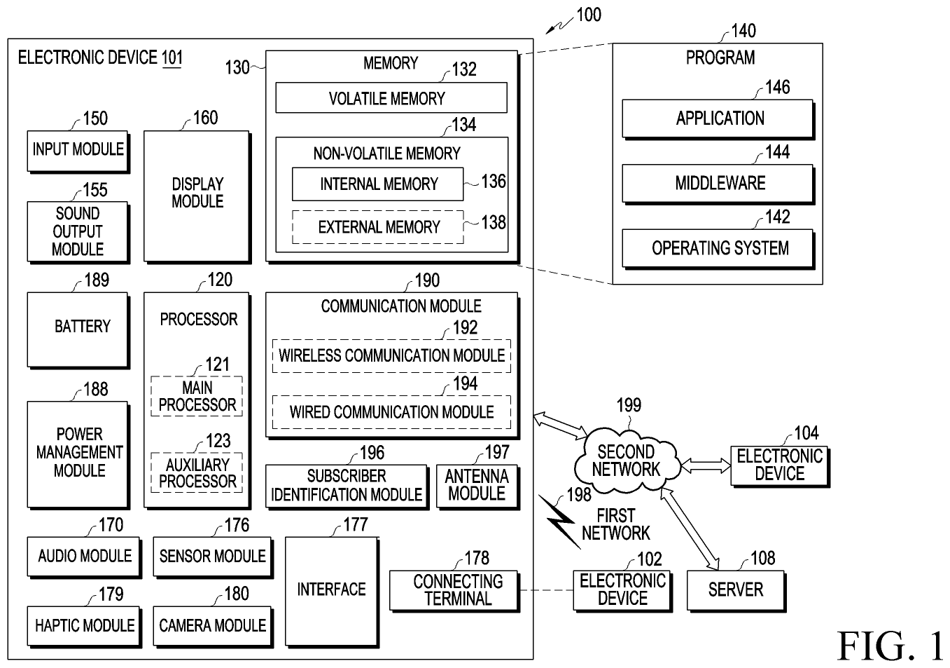

FIG. 1 is a block diagram illustrating an electronic device 101 in a network environment 100 according to various embodiments. Referring to FIG. 1, the electronic device 101 in the network environment 100 may communicate with at least one of an electronic device 102 via a first network 198 (e.g., a short-range wireless communication network), or an electronic device 104 or a server 108 via a second network 199 (e.g., a long-range wireless communication network). According to an embodiment, the electronic device 101 may communicate with the electronic device 104 via the server 108. According to an embodiment, the electronic device 101 may include a processor 120, memory 130, an input module 150, a sound output module 155, a display module 160, an audio module 170, a sensor module 176, an interface 177, a connecting terminal 178, a haptic module 179, a camera module 180, a power management module 188, a battery 189, a communication module 190, a subscriber identification module (SIM) 196, or an antenna module 197. In an embodiment, at least one (e.g., the connecting terminal 178) of the components may be omitted from the electronic device 101, or one or more other components may be added in the electronic device 101. According to an embodiment, some (e.g., the sensor module 176, the camera module 180, or the antenna module 197) of the components may be integrated into a single component (e.g., the display module 160).

The processor 120 may execute, for example, software (e.g., a program 140) to control at least one other component (e.g., a hardware or software component) of the electronic device 101 coupled with the processor 120, and may perform various data processing or computation. According to an embodiment, as at least part of the data processing or computation, the processor 120 may store a command or data received from another component (e.g., the sensor module 176 or the communication module 190) in volatile memory 132, process the command or the data stored in the volatile memory 132, and store resulting data in non-volatile memory 134. According to an embodiment, the processor 120 may include a main processor 121 (e.g., a central processing unit (CPU) or an application processor (AP)), or an auxiliary processor 123 (e.g., a graphics processing unit (GPU), a neural processing unit (NPU), an image signal processor (ISP), a sensor hub processor, or a communication processor (CP)) that is operable independently from, or in conjunction with, the main processor 121. For example, when the electronic device 101 includes the main processor 121 and the auxiliary processor 123, the auxiliary processor 123 may be configured to use lower power than the main processor 121 or to be specified for a designated function. The auxiliary processor 123 may be implemented as separate from, or as part of the main processor 121.

The auxiliary processor 123 may control at least some of functions or states related to at least one component (e.g., the display module 160, the sensor module 176, or the communication module 190) among the components of the electronic device 101, instead of the main processor 121 while the main processor 121 is in an inactive (e.g., sleep) state, or together with the main processor 121 while the main processor 121 is in an active state (e.g., executing an application). According to an embodiment, the auxiliary processor 123 (e.g., an image signal processor or a communication processor) may be implemented as part of another component (e.g., the camera module 180 or the communication module 190) functionally related to the auxiliary processor 123. According to an embodiment, the auxiliary processor 123 (e.g., the neural processing unit) may include a hardware structure specified for artificial intelligence model processing. The artificial intelligence model may be generated via machine learning. Such learning may be performed, e.g., by the electronic device 101 where the artificial intelligence is performed or via a separate server (e.g., the server 108). Learning algorithms may include, but are not limited to, e.g., supervised learning, unsupervised learning, semi-supervised learning, or reinforcement learning. The artificial intelligence model may include a plurality of artificial neural network layers. The artificial neural network may be a deep neural network (DNN), a convolutional neural network (CNN), a recurrent neural network (RNN), a restricted Boltzmann machine (RBM), a deep belief network (DBN), a bidirectional recurrent deep neural network (BRDNN), deep Q-network or a combination of two or more thereof but is not limited thereto. The artificial intelligence model may, additionally or alternatively, include a software structure other than the hardware structure.

The memory 130 may store various data used by at least one component (e.g., the processor 120 or the sensor module 176) of the electronic device 101. The various data may include, for example, software (e.g., the program 140) and input data or output data for a command related thereto. The memory 130 may include the volatile memory 132 or the non-volatile memory 134.

The program 140 may be stored in the memory 130 as software, and may include, for example, an operating system (OS) 142, middleware 144, or an application 146.

The input module 150 may receive a command or data to be used by other component (e.g., the processor 120) of the electronic device 101, from the outside (e.g., a user) of the electronic device 101. The input module 150 may include, for example, a microphone, a mouse, a keyboard, keys (e.g., buttons), or a digital pen (e.g., a stylus pen).

The sound output module 155 may output sound signals to the outside of the electronic device 101. The sound output module 155 may include, for example, a speaker or a receiver. The speaker may be used for general purposes, such as playing multimedia or playing record. The receiver may be used for receiving incoming calls. According to an embodiment, the receiver may be implemented as separate from, or as part of the speaker.

The display module 160 may visually provide information to the outside (e.g., a user) of the electronic device 101. The display 160 may include, for example, a display, a hologram device, or a projector and control circuitry to control a corresponding one of the display, hologram device, and projector. According to an embodiment, the display 160 may include a touch sensor configured to detect a touch, or a pressure sensor configured to measure the intensity of a force generated by the touch.

The audio module 170 may convert a sound into an electrical signal and vice versa. According to an embodiment, the audio module 170 may obtain the sound via the input module 150, or output the sound via the sound output module 155 or a headphone of an external electronic device (e.g., an electronic device 102) directly (e.g., wiredly) or wirelessly coupled with the electronic device 101.

The sensor module 176 may detect an operation state (e.g., power or temperature) of the electronic device 101 or an environmental state (e.g., a state of a user) external to the electronic device 101, and then generate an electrical signal or data value corresponding to the detected state. According to an embodiment, the sensor module 176 may include, for example, a gesture sensor, a gyro sensor, an atmospheric pressure sensor, a magnetic sensor, an accelerometer, a grip sensor, a proximity sensor, a color sensor, an infrared (IR) sensor, a biometric sensor, a temperature sensor, a humidity sensor, or an illuminance sensor.

The interface 177 may support one or more specified protocols to be used for the electronic device 101 to be coupled with the external electronic device (e.g., the electronic device 102) directly (e.g., wiredly) or wirelessly. According to an embodiment, the interface 177 may include, for example, a high definition multimedia interface (HDMI), a universal serial bus (USB) interface, a secure digital (SD) card interface, or an audio interface.

A connecting terminal 178 may include a connector via which the electronic device 101 may be physically connected with the external electronic device (e.g., the electronic device 102). According to an embodiment, the connecting terminal 178 may include, for example, an HDMI connector, a USB connector, an SD card connector, or an audio connector (e.g., a headphone connector).

The haptic module 179 may convert an electrical signal into a mechanical stimulus (e.g., a vibration or motion) or electrical stimulus which may be recognized by a user via his tactile sensation or kinesthetic sensation. According to an embodiment, the haptic module 179 may include, for example, a motor, a piezoelectric element, or an electric stimulator.

The camera module 180 may capture a still image or moving images. According to an embodiment, the camera module 180 may include one or more lenses, image sensors, image signal processors, or flashes.

The power management module 188 may manage power supplied to the electronic device 101. According to an embodiment, the power management module 188 may be implemented as at least part of, for example, a power management integrated circuit (PMIC).

The battery 189 may supply power to at least one component of the electronic device 101. According to an embodiment, the battery 189 may include, for example, a primary cell which is not rechargeable, a secondary cell which is rechargeable, or a fuel cell.

The communication module 190 may support establishing a direct (e.g., wired) communication channel or a wireless communication channel between the electronic device 101 and the external electronic device (e.g., the electronic device 102, the electronic device 104, or the server 108) and performing communication via the established communication channel. The communication module 190 may include one or more communication processors that are operable independently from the processor 120 (e.g., the application processor (AP)) and supports a direct (e.g., wired) communication or a wireless communication. According to an embodiment, the communication module 190 may include a wireless communication module 192 (e.g., a cellular communication module, a short-range wireless communication module, or a global navigation satellite system (GNSS) communication module) or a wired communication module 194 (e.g., a local area network (LAN) communication module or a power line communication (PLC) module). A corresponding one of these communication modules may communicate with the external electronic device 104 via a first network 198 (e.g., a short-range communication network, such as Bluetooth™, wireless-fidelity (Wi-Fi) direct, or infrared data association (IrDA)) or a second network 199 (e.g., a long-range communication network, such as a legacy cellular network, a 5G network, a next-generation communication network, the Internet, or a computer network (e.g., local area network (LAN) or wide area network (WAN)). These various types of communication modules may be implemented as a single component (e.g., a single chip), or may be implemented as multi components (e.g., multi chips) separate from each other. The wireless communication module 192 may identify or authenticate the electronic device 101 in a communication network, such as the first network 198 or the second network 199, using subscriber information (e.g., international mobile subscriber identity (IMSI)) stored in the subscriber identification module 196.

The wireless communication module 192 may support a 5G network, after a 4G network, and next-generation communication technology, e.g., new radio (NR) access technology. The NR access technology may support enhanced mobile broadband (eMBB), massive machine type communications (mMTC), or ultra-reliable and low-latency communications (URLLC). The wireless communication module 192 may support a high-frequency band (e.g., the mmWave band) to achieve, e.g., a high data transmission rate. The wireless communication module 192 may support various technologies for securing performance on a high-frequency band, such as, e.g., beamforming, massive multiple-input and multiple-output (massive MIMO), full dimensional MIMO (FD-MIMO), array antenna, analog beam-forming, or large scale antenna. The wireless communication module 192 may support various requirements specified in the electronic device 101, an external electronic device (e.g., the electronic device 104), or a network system (e.g., the second network 199). According to an embodiment, the wireless communication module 192 may support a peak data rate (e.g., 20 Gbps or more) for implementing eMBB, loss coverage (e.g., 164 dB or less) for implementing mMTC, or U-plane latency (e.g., 0.5 ms or less for each of downlink (DL) and uplink (UL), or a round trip of 1 ms or less) for implementing URLLC.

The antenna module 197 may transmit or receive a signal or power to or from the outside (e.g., the external electronic device). According to an embodiment, the antenna module 197 may include one antenna including a radiator formed of a conductor or conductive pattern formed on a substrate (e.g., a printed circuit board (PCB)). According to an embodiment, the antenna module 197 may include a plurality of antennas (e.g., an antenna array). In this case, at least one antenna appropriate for a communication scheme used in a communication network, such as the first network 198 or the second network 199, may be selected from the plurality of antennas by, e.g., the communication module 190. The signal or the power may then be transmitted or received between the communication module 190 and the external electronic device via the selected at least one antenna. According to an embodiment, other parts (e.g., radio frequency integrated circuit (RFIC)) than the radiator may be further formed as part of the antenna module 197.

According to an embodiment, the antenna module 197 may form a mmWave antenna module. According to an embodiment, the mmWave antenna module may include a printed circuit board, a RFIC disposed on a first surface (e.g., the bottom surface) of the printed circuit board, or adjacent to the first surface and capable of supporting a designated high-frequency band (e.g., the mmWave band), and a plurality of antennas (e.g., array antennas) disposed on a second surface (e.g., the top or a side surface) of the printed circuit board, or adjacent to the second surface and capable of transmitting or receiving signals of the designated high-frequency band.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

According to an embodiment, instructions or data may be transmitted or received between the electronic device 101 and the external electronic device 104 via the server 108 coupled with the second network 199. The external electronic devices 102 or 104 each may be a device of the same or a different type from the electronic device 101. According to an embodiment, all or some of operations to be executed at the electronic device 101 may be executed at one or more of the external electronic devices 102, 104, or 108. For example, if the electronic device 101 should perform a function or a service automatically, or in response to a request from a user or another device, the electronic device 101, instead of, or in addition to, executing the function or the service, may request the one or more external electronic devices to perform at least part of the function or the service. The one or more external electronic devices receiving the request may perform the at least part of the function or the service requested, or an additional function or an additional service related to the request, and transfer an outcome of the performing to the electronic device 101. The electronic device 101 may provide the outcome, with or without further processing of the outcome, as at least part of a reply to the request. To that end, a cloud computing, distributed computing, mobile edge computing (MEC), or client-server computing technology may be used, for example. The electronic device 101 may provide ultra low-latency services using, e.g., distributed computing or mobile edge computing. In another embodiment, the external electronic device 104 may include an Internet-of-things (IoT) device. The server 108 may be an intelligent server using machine learning and/or a neural network. According to an embodiment, the external electronic device 104 or the server 108 may be included in the second network 199. The electronic device 101 may be applied to intelligent services (e.g., smart home, smart city, smart car, or healthcare) based on 5G communication technology or IoT-related technology.

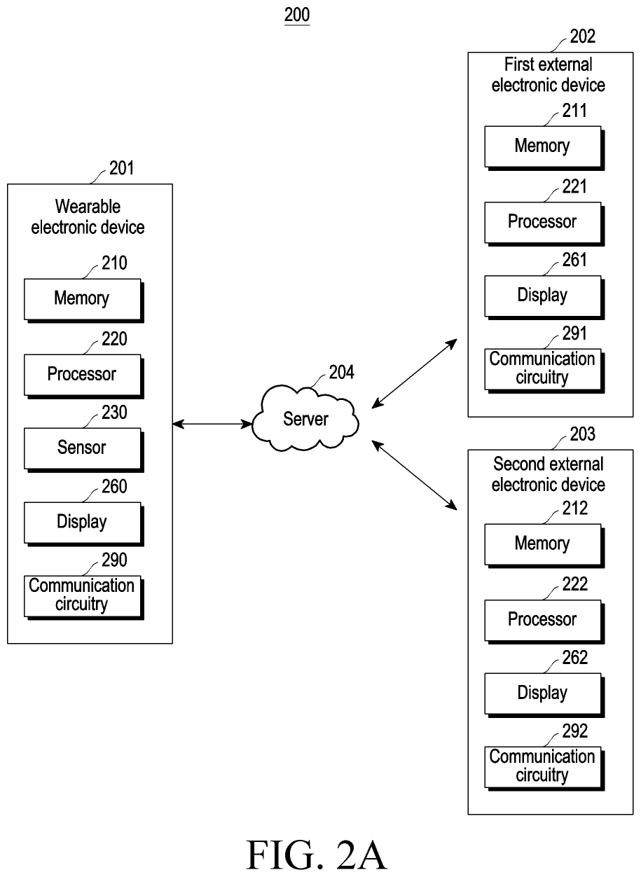

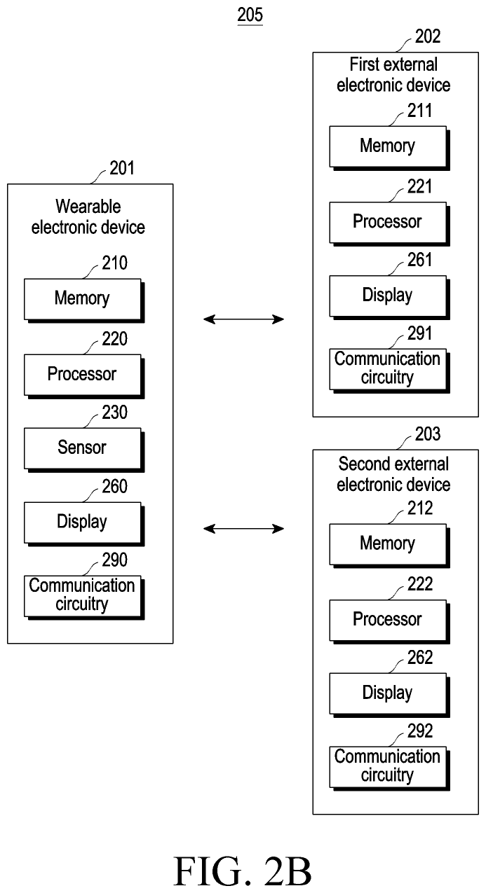

FIG. 2A is a view illustrating a system including a wearable electronic device, a first external electronic device, a second external electronic device, and a server.

Referring to FIG. 2A, according to an embodiment, the system 200 may include a wearable electronic device 201, a first external electronic device 202, a second external electronic device 203, and a server 204. For example, the wearable electronic device 201, the first external electronic device 202, and the second external electronic device 203 may be implemented to be identical or similar to the electronic device 101, 102, or 104 of FIG. 1. The server 204 may be implemented to be identical or similar to the server 108 of FIG. 1.

According to an embodiment, the system 200 may include a system in which each of the wearable electronic device 201, the first external electronic device 202, and the second external electronic device 203 is connected through the server 204. According to an embodiment, when it is determined that the wearable electronic device 201 is not worn on the user's body, the system 200 may include a system for continuously executing a function being executed on the wearable electronic device 201 on at least one external electronic device 202 and 203. The wearable electronic device 201 may be connected to the server 204 using authentication information (e.g., login information, account information, or identification information) specified in the wearable electronic device 201. According to an embodiment, the at least one external electronic device 202 and 203 may be connected to the server 204 using the same authentication information (e.g., the same login information, account information, or identification information) as the authentication information specified in the wearable electronic device 201.

In an exemplary embodiment, an wearable electronic device may be worn on the body when the wearable electronic device is carried on or is on a person or on a body of the person or when the wearable electronic device is carried. By being worn, the wearable electronic device may be worn directly on, over, or through appendages, the trunk, the head and neck, and other external or internal parts of the body. The wearable electronic device may be in direct contact with the skin or not in direct contact with the skin and may be carried by the person over or on clothing or over or on other articles or objects carried by the person. In contrast, the unwearing of the wearable electronic device may be the opposite of the wearing of the wearable electronic device on the body.

According to an embodiment, the operation of continuously executing the first function being executed on the wearable electronic device 201 on the at least one external electronic device 202 and 203 may indicate a series of operations in which the wearable electronic device 201 stops the first function being executed on the wearable electronic device 201 and transmits information related to the first function to the at least one external electronic device 202 and 203, and the at least one external electronic device 202 and 203 executes a second function corresponding to the first function stored in the at least one external electronic device 202 and 203 using the information related to the first function.

According to an embodiment, the function may include a function that may be executed on the wearable electronic device 201. For example, the function may include a function related to an application of wearable electronic device 201.

According to an embodiment, the at least one external electronic device 202 and 203 may continuously execute the function being executed on the wearable electronic device 201 by executing an application corresponding to the application of the wearable electronic device 201 (e.g., an application performing the same function). For example, when it is determined that the user is not using the wearable electronic device 201, the system 200 may continuously execute the function being executed on the wearable electronic device 201 on the at least one external electronic device 202 and 203. According to an embodiment, the wearable electronic device 201 may stop the function being executed, and the at least one external electronic device 202 and 203 may continue to execute the corresponding function from the time when the function being executed on the wearable electronic device 201 is stopped. For example, when it is determined that the user is not using the wearable electronic device 201, the system 200 may stop the function being executed on the wearable electronic device 201 and continuously execute the function on the at least one external electronic device 202 and 203. For example, the at least one external electronic device 202 and 203 may include an electronic device in use by the user and/or an electronic device in an activated state.

The system 200 according to an embodiment may allow the user to continuously perform the corresponding function by executing the function being executed on the wearable electronic device 201 on the at least one external electronic device 202 and 203 when the wearable electronic device 201 is not worn on the user's body. Further, the system 200 may stop the function executed on the wearable electronic device 201 that the user is not using, thereby preventing unnecessary battery consumption and heat generation in the wearable electronic device 201.

According to an embodiment, when the wearable electronic device 201 is not worn on the user's body, the user may not be aware of the function being executed on the wearable electronic device 201. The system 200 according to an embodiment may, when the wearable electronic device 201 is not worn on the user's body, allow the function being executed on the wearable electronic device 201 to be executed on the at least one external electronic device 202 and 203 identified in a state in which the display is turned on so that the user recognizes the corresponding function.

According to an embodiment, the wearable electronic device 201 (e.g., the electronic device 101 of FIG. 1) may include memory 210 (e.g., the memory 130 of FIG. 1), a processor 220 (e.g., the processor 120 of FIG. 1), a sensor 230 (e.g., the sensor module 176 of FIG. 1), a display 260 (e.g., the display module 160 of FIG. 1), and communication circuitry 290 (e.g., the communication module 190 of FIG. 1). According to an embodiment, the processor 220 may control the overall operation of the wearable electronic device 201.

According to an embodiment, the first external electronic device 202 (e.g., the electronic device 101 of FIG. 1) may include memory 211 (e.g., the memory 130 of FIG. 1), a processor 221 (e.g., the processor 120 of FIG. 1), a display 261 (e.g., the display module 160 of FIG. 1), and communication circuitry 291 (e.g., the communication module 190 of FIG. 1). According to an embodiment, the processor 221 may control the overall operation of the first external electronic device 202. For example, the first external electronic device 202 may be implemented as a wearable electronic device that may be worn on the user's body, a smartphone, a tablet PC, a computing device, or a TV. However, this is an example, and the first external electronic device 202 may be implemented as various devices.

According to an embodiment, the second external electronic device 203 (e.g., the electronic device 101 of FIG. 1) may include memory 212 (e.g., the memory 130 of FIG. 1), a processor 222 (e.g., the processor 120 of FIG. 1), a display 262 (e.g., the display module 160 of FIG. 1), and communication circuitry 292 (e.g., the communication module 190 of FIG. 1). According to an embodiment, the processor 222 may control the overall operation of the second external electronic device 203. For example, the second external electronic device 203 may be implemented as a wearable electronic device that may be worn on the user's body, a smartphone, a tablet PC, a computing device, or a TV. However, this is an example, and the second external electronic device 203 may be implemented as various devices.

According to an embodiment, the processor 220 may execute at least one function of the wearable electronic device 201. According to an embodiment, the at least one function may include a function related to at least one application of the wearable electronic device 201. For example, the at least one function may include audio recording-related functions, call-related functions, exercise-related functions, timer-related functions, content playback-related functions, functions related to remote controls that may control other external electronic devices, memo-related functions, or notification output-related functions. However, this is an example, and the at least one function may not be limited thereto.

According to an embodiment, while executing at least one function, the processor 220 may determine that the wearable electronic device 201 is not worn on the user's body through the sensor 230. For example, the sensor 230 may include at least one of an acceleration sensor, an infrared sensor, a gyro sensor, or a biometric sensor that detects heart rate, heart signals, skin temperature, and other biometric signals. For example, the processor 220 may determine that the wearable electronic device 201 is not worn on the user's body through the sensor 230 (e.g., an infrared sensor). For example, the processor 220 may determine that the wearable electronic device 201 is not worn on the user's body based on determining that there is no movement of the wearable electronic device 201 through the sensor 230 (e.g., an acceleration sensor, a gyro sensor), or if a biometric signal is not detected.

According to an embodiment, the processor 220 may identify the at least one external electronic device 202 and 203 around the wearable electronic device 201 based on determining that the wearable electronic device 201 is not worn on the user's body. For example, based on determining that the wearable electronic device 201 is not worn on the user's body, the processor 220 may transmit a message (e.g., a command) requesting information related to the at least one external electronic device 202 and 203 connected to the server 204 using the same authentication information as the authentication information specified in the wearable electronic device 201. The server 204 may transmit the information related to the at least one external electronic device 202 and 203 to the wearable electronic device 201 based on receiving the message. According to an embodiment, the information related to the at least one external electronic device 202 and 203 may include at least one of information about the activated state of the at least one external electronic device 202 and 203, information about the number of user inputs input to each of the at least one external electronic device 202 and 203, or information about the type and wearing state of the at least one external electronic device 202 and 203. According to an embodiment, the activated state of the at least one external electronic device 202 and 203 may include a state in which the display of the at least one external electronic device 202 and 203 is turned on or a state in which the level of the battery of the at least one external electronic device 202 and 203 is higher than a specified level.

According to an embodiment, the processor 220 may identify the first external electronic device 202 that meets a specified condition among the at least one external electronic device 202 and 203, based on the information related to the at least one external electronic device 202 and 203. For example, the specified condition may include a condition for a device capable of continuously executing at least one function being executed by the wearable electronic device 201.

According to an embodiment, when it is identified that the first external electronic device 202 is in the activated state, the processor 220 may identify that the first external electronic device 202 satisfies a specified condition. According to an embodiment, the activated state may include a state in which the display of the first external electronic device 202 is turned on or a state in which the level of the battery of the first external electronic device 202 is higher than a specified level. For example, the specified level may represent the remaining amount of battery for executing at least one function being executed on the wearable electronic device 201. For example, the specified level may be set by the user or automatically set by processor 220.

According to an embodiment, the processor 220 may identify that the first external electronic device 202 satisfies the specified condition based on determining that the first external electronic device 202 is a device wearable on the user's body and that the first external electronic device 202 is worn on the user's body.

According to an embodiment, the processor 220 may identify the number of user inputs input to each of the at least one external electronic device 202 and 203. According to an embodiment, when it is identified that the number of user inputs input to the first external electronic device 202 is the largest, i.e., the number of user inputs input to the first external electronic device 202 is larger than the number of user inputs input to the second external electronic device 203, the processor 220 may identify that the first external electronic device 202 satisfies the specified condition.

According to an embodiment, the processor 220 may identify whether at least one function is executable on the first external electronic device 202 based on identifying that the first external electronic device 202 satisfies the specified condition. According to an embodiment, when it is identified that the first external electronic device 202 does not include a hardware component or a software component required to execute at least one function, the processor 220 may identify that at least one function is not executable on the first external electronic device 202. For example, when it is identified that the at least one function is related to audio recording, and the first external electronic device 202 is a device that does not include a microphone (and speaker), the processor 220 may identify that the at least one function is not executable on the first external electronic device 202. For example, when it is identified that the at least one function is related to a call, and the first external electronic device 202 is a device that does not include a speaker and a microphone, the processor 220 may identify that the at least one function is not executable on the first external electronic device 202. According to an embodiment, when it is identified that the first external electronic device 202 may not execute at least one function, the processor 220 may transmit a message to the second external electronic device 203 for displaying information indicating that the second external electronic device 203 capable of executing at least one function may execute at least one function on the display 262.

According to an embodiment, the processor 220 may transmit a first message to the server 204 to display information indicating that the at least one function may be executed on the first external electronic device 202, based on identifying that the at least one function is executable on the first external electronic device 202. According to an embodiment, the server 204 may transmit the first message to the first external electronic device 202. According to an embodiment, the processor 220 may transmit a first message further including information indicating that the at least one function is being executed on the wearable electronic device 201 to the server 204.

According to an embodiment, the processor 220 may provide the first message to the server 204 based on history information related to at least one function stored in the wearable electronic device 201. For example, the history information may include information about at least one of the frequency at which at least one function is continuously executed by at least one external electronic device, the time when the function is continuously executed, or the location where that function is continuously executed. For example, the processor 220 may transmit the first message to the server 204 to provide the first message to the first external electronic device 202 with the highest frequency of continuously executing at least one function at the current location identified by the wearable electronic device 201 based on the history information. For example, the processor 220 may transmit the first message to the server 204 to provide the first message to the first external electronic device 202 with the highest frequency of continuously executing at least one function at the current time identified by the wearable electronic device 201 based on the history information.

According to an embodiment, the processor 221 may display, on the display 261, information indicating that the at least one function may be executed on the first external electronic device 202 based on receiving the first message from the server 204. According to an embodiment, the processor 221 may display, on the display 261, information indicating that the at least one function is being executed on the wearable electronic device 201 based on receiving the first message from the server 204.

According to an embodiment, the processor 221 may transmit a second message requesting information for executing the first function to the server 204 through the communication circuitry 291 based on identifying a user input for executing the first function among the at least one function. According to an embodiment, the server 204 may transmit the second message to the wearable electronic device 201.

According to an embodiment, the processor 220 may transmit information related to the first function to the server 204 based on receiving the second message from the server 204. According to an embodiment, the server 204 may transmit the information related to the first function to the first external electronic device 202. The information related to the first function may include an application related to the first function, a time when the first function is executed, and information about the progress state of the first function.

According to an embodiment, the processor 220 may stop executing the first function based on transmitting the information related to the first function to the server 204.

According to an embodiment, the processor 221 may execute the first function based on receiving the information related to the first function from the server 204. According to an embodiment, the processor 221 may continuously execute the first function being executed on the wearable electronic device 201. For example, the processor 221 may continuously execute the first function by executing an application corresponding to the application of the wearable electronic device 201 (e.g., an application performing the same function). For example, the processor 221 may continuously execute the first function from the time when the first function is stopped in the wearable electronic device 201.

For example, when the first function is a timer-related function, the processor 221 may continuously execute the first function (e.g., restart the timer from the time when the timer is stopped) based on the time when the timer is stopped in the wearable electronic device 201. For example, when the first function is a function related to playing content, the processor 221 may continuously execute the first function (e.g., play content from the time when it is stopped) based on the time when the playback of the content is stopped in the wearable electronic device 201. For example, when the first function is an exercise-related function, the processor 221 may continuously execute the first function (e.g., measure biometric information from the time when the measurement of biometric information is stopped) based on the biometric signal in the wearable electronic device 201.

According to an embodiment, the processor 220 may include information for displaying the second function and the third function as one group based on identifying that the third function among the at least one function has been executed within a specified time (e.g., 1 minute) from the time when the second function among the at least one function is executed, in the first message. According to an embodiment, the processor 221 may display the second function and the third function as one group based on the first message. The processor 221 may display information indicating that the second function and the third function included in one group may be executed at the same time. The processor 221 may execute the second function and the third function included in one group at the same time.

According to an embodiment, the processor 221 may further display information indicating that the at least one function may be executed on another external electronic device (e.g., the second external electronic device 203) other than the first external electronic device 202. For example, the other external electronic device may include a device connected to the first external electronic device 202 using a short-range communication technology through the communication circuitry 291. For example, the other external electronic device may include a device connected to the server 204 using the same authentication information as the authentication information stored in the wearable electronic device 201 through the server 204. According to an embodiment, the processor 221 may provide a message requesting information related to at least one function for executing at least one function on the second external electronic device 203 to the wearable electronic device 201 through the server 204. According to an embodiment, the processor 220 may provide information related to at least one function to the first external electronic device 202 through the server 204. According to an embodiment, the processor 221 may provide information related to at least one function to the second external electronic device 203. According to an embodiment, the processor 220 may provide information related to at least one function to the second external electronic device 203 through the server 204.

According to an embodiment, the processor 221 may further display information indicating that the first external electronic device 202 may control to terminate at least one function being executed on the wearable electronic device 201 without executing at least one function. For example, when a user input for terminating at least one function being executed on the wearable electronic device 201 is obtained, the processor 221 may provide the wearable electronic device 201 with a message for terminating at least one function being executed on the wearable electronic device 201 through the server 204. The processor 220 may terminate at least one function based on the message.

According to an embodiment, when the first external electronic device 202 specified in advance to execute the first function is identified, the processor 220 may provide the information related to the first function to the first external electronic device 202 through the server 204. Accordingly, the first external electronic device 202 may automatically execute the first function even when a user input for executing the first function is not identified.

According to an embodiment, the processor 220 may provide information related to a specified function among the at least one function to the first external electronic device 202 and the second external electronic device 203 identified through the communication circuitry 290. For example, the specified function may include a function related to an output of a notification. Accordingly, the specified function currently executed on the wearable electronic device 201 may be automatically executed on devices identified to be positioned around the wearable electronic device 201 even when a user input for executing the specified function is not identified.

According to an embodiment, the processor 220 may provide information related to the first function to the first external electronic device 202 to execute the first function executable on the first external electronic device 202 among the at least one function based on determining that the first external electronic device 202 is worn on the user's body. Accordingly, the wearable electronic device 201 may automatically execute the first function even when a user input for executing the first function in the first external electronic device 202 worn on the user's body is not identified.

According to an embodiment, when it is identified that the at least one function is information related to the playback of the content, the processor 220 may identify a device capable of playing content among the at least one external electronic devices 202 and 203. For example, the device capable of playing content may represent a device including a display and a speaker. According to an embodiment, the processor 220 may provide information related to the content to the device capable of playing content among the at least one external electronic device 202 and 203 through the server 204 to play the content. Accordingly, the device capable of playing content among the at least one external electronic device 202 and 203 may mirror and display the content being played on the wearable electronic device 201.

FIG. 2B is a view illustrating a system including a wearable electronic device, a first external electronic device, and a second external electronic device.

Referring to FIG. 2B, according to an embodiment, the system 205 may include a wearable electronic device 201 (e.g., the wearable electronic device 201 of FIG. 2A), a first external electronic device 202 (e.g., the first external electronic device 202 of FIG. 2A), and a second external electronic device 203 (e.g., the second external electronic device 203 of FIG. 2A). According to an embodiment, the description of FIG. 2 may be applied to the description of the wearable electronic device 201, the first external electronic device 202, and the second external electronic device 203.

The system 205 of FIG. 2B may not include a server 204 (e.g., the server 204 of FIG. 2A) compared to the system 200 of FIG. 2A. The system 200 may include a system in which each of the wearable electronic device 201, the first external electronic device 202, and the second external electronic device 203 is directly connected without the server 204. According to an embodiment, the wearable electronic device 201 may identify the at least one external electronic device 202 and 203 connected to the wearable electronic device 201 using a short-range communication technology through the communication circuitry 290. The short-range communication technology may include Wi-Fi communication technology and Bluetooth low energy (BLE) communication technology. According to an embodiment, the wearable electronic device 201 may directly transmit/receive information to/from the at least one external electronic device 202 and 203 connected to the wearable electronic device 201 using a short-range communication technology.

According to an embodiment, the operation in which the wearable electronic device 201 described in connection with FIG. 2A transmits/receives information to/from the at least one external electronic device 202 and 203 through the server 204 may be replaced with an operation in which the wearable electronic device 201 directly transmits/receives information to/from at least one external electronic device 202 and 203.

Operations of the wearable electronic device 201 described below may be performed by the processor 220. However, for convenience of description, it is described that the operations performed by the processor 220 are performed by the wearable electronic device 201.

The operations of the first external electronic device 202 described in the drawings may be performed by the processor 221. However, for convenience of description, the operations performed by the processor 221 are described as being performed by the first external electronic device 202.

The operations of the second external electronic device 203 described in the drawings may be performed by the processor 222. However, for convenience of description, the operations performed by the processor 222 are described as being performed by the second external electronic device 203.

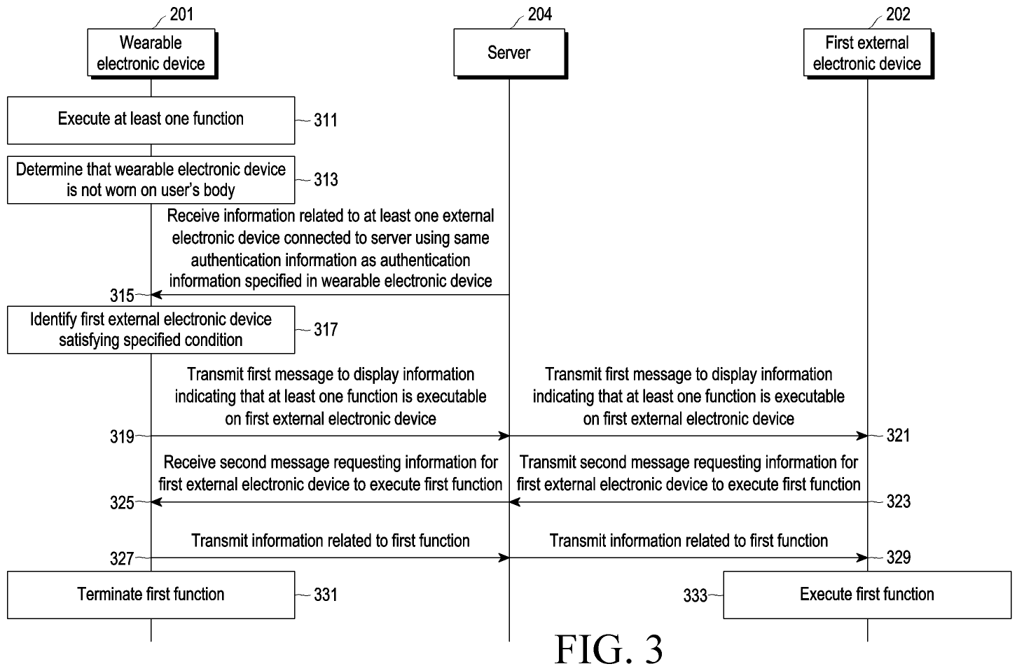

FIG. 3 is a view illustrating an operation of providing information related to a function being executed by the wearable electronic device to the first external electronic device according to an embodiment.

In the following embodiment, each operation may be sequentially performed, but is not necessarily performed sequentially. For example, the order of the operations may be changed, and at least two operations may be performed in parallel.

Referring to FIG. 3, according to an embodiment, the wearable electronic device 201 (e.g., the wearable electronic device 201 of FIG. 2A) may be connected to the server 204 (e.g., the server 204 of FIG. 2A) using authentication information specified in the wearable electronic device 201.

According to an embodiment, in operation 311, the wearable electronic device 201 may execute at least one function of the wearable electronic device 201. According to an embodiment, the at least one function may include a function related to at least one application of the wearable electronic device 201. For example, the at least one function may include a function related to audio recording, a function related to a call, a function related to exercise, a function related to a timer, a function related to playing content, a function related to a memo, or a function related to an output of a notification.

According to an embodiment, in operation 313, the wearable electronic device 201 may determine that the wearable electronic device 201 is not worn on the user's body through the sensor 230 (e.g., the sensor 230 of FIG. 2A) while executing at least one function. For example, the wearable electronic device 201 may determine through the sensor 230 (e.g., an infrared sensor) that the wearable electronic device 201 is not being worn on the user's body. For example, the wearable electronic device 201 may determine that the wearable electronic device 201 is not worn on the user's body based on determining that there is no movement of the wearable electronic device 201 through the sensor 230 (e.g., an acceleration sensor, a gyro sensor).

According to an embodiment, in operation 315, the wearable electronic device 201 may receive information related to at least one external electronic device 202 or 203 (e.g., the first external electronic device 202 of FIG. 2A, the second external electronic device 203 of FIG. 2A) connected to (or accessing) the server 204 from the server 204 based on determining that the wearable electronic device 201 is not worn on the user's body. For example, the at least one external electronic device 202 and 203 may include an electronic device connected to (or accessing) the server 204 using the same authentication information as the authentication information specified in the wearable electronic device 201.

According to an embodiment, the wearable electronic device 201 may transmit, to the server 204, a message requesting the information related to the at least one external electronic device 202 and 203 connected to the server 204 using the same authentication information as the authentication information specified in the wearable electronic device 201 based on determining that the wearable electronic device 201 is not worn on the user's body. The server 204 may transmit the information related to the at least one external electronic device 202 and 203 to the wearable electronic device 201 based on receiving the message.

According to an embodiment, the information related to the at least one external electronic device 202 and 203 may include at least one of information about the activated state of the at least one external electronic device 202 and 203, information about the number of user inputs input to the at least one external electronic device 202 and 203, or information about the type and wearing state of the at least one external electronic device 202 and 203. According to an embodiment, the activated state of the at least one external electronic device 202 and 203 may include a state in which the display of the at least one external electronic device 202 and 203 is turned on or a state in which the level of the battery of the at least one external electronic device 202 and 203 is higher than a specified level.

According to an embodiment, in operation 317, the wearable electronic device 201 may identify a first external electronic device 202 that satisfies the specified condition among the at least one external electronic device based on the information related to the at least one external electronic device 202 and 203. For example, the specified condition may include a condition for a device capable of continuously executing at least one function being executed by the wearable electronic device 201.

According to an embodiment, in operation 319, the wearable electronic device 201 may transmit a first message to the server 204 to allow the first external electronic device 202 to display information indicating that the at least one function may be executed on the first external electronic device 202. According to an embodiment, the first message may further include information that allows the first external electronic device 202 to display a notification (information) indicating that the at least one function is being executed on the wearable electronic device 201.

According to an embodiment, in operation 321, the server 204 may transmit a first message to the first external electronic device 202 to allow the first external electronic device 202 to display information indicating that the at least one function may be executed on the first external electronic device 202. According to an embodiment, the first external electronic device 202 may display information indicating that the at least one function may be executed on the first external electronic device 202 on the display 261 (e.g., the display 261 of FIG. 2A) based on receiving the first message. According to an embodiment, the first external electronic device 202 may further display information indicating that the at least one function is being executed on the wearable electronic device 201 on the display 261 based on receiving the first message.

According to an embodiment, in operation 323, the first external electronic device 202 may transmit, to the server 204, a second message requesting information for the first external electronic device 202 to execute the first function. According to an embodiment, the first external electronic device 202 may transmit, to the server 204, a second message requesting information for the first external electronic device 202 to execute the first function based on identifying a user input for executing the first function among the at least one function.

According to an embodiment, in operation 325, the wearable electronic device 201 may receive, from the server 204, a second message requesting information for the first external electronic device to execute the first function.

According to an embodiment, in operation 327, the wearable electronic device 201 may transmit the information related to the first function to the server 204 based on receiving the second message. For example, the information related to the first function may include an application related to the first function capable of executing the first function, a time when the first function is executed, and information about the progress state of the first function.

According to an embodiment, in operation 329, the server 204 may transmit the information related to the first function to the first external electronic device 202.

According to an embodiment, in operation 331, the wearable electronic device 201 may terminate the first function based on transmitting the information related to the first function to the server 204. According to the implementation, the wearable electronic device 201 may execute the first function (e.g., for a predetermined time) without terminating the first function.

According to an embodiment, in operation 333, the first external electronic device 202 may execute the first function based on receiving the information related to the first function. For example, the first external electronic device 202 may continuously execute the first function from the time when the first function is stopped in the wearable electronic device 201. For example, when the first function is a timer-related function, the first external electronic device 202 may continuously execute the first function (e.g., restart the timer from the time when the timer is stopped) based on the time when the timer is stopped in the wearable electronic device 201. For example, when the first function is a function related to playing content, the first external electronic device 202 may continuously execute the first function (e.g., play content from the time when it is stopped) based on the time when the playback of the content is stopped in the wearable electronic device 201.

According to an embodiment, in embodiments of the disclosure, operation 313 may be performed after operation 317. For example, the wearable electronic device 201 may execute at least one function in operation 311. Thereafter, in operation 315, the wearable electronic device 201 may receive information related to at least one external electronic device connected to the server 204 using the same authentication information as the authentication information specified in the wearable electronic device 201. Thereafter, in operation 317, the wearable electronic device 201 may identify the first external electronic device 202 that satisfies the specified condition. Thereafter, in operation 313, the wearable electronic device 201 may determine that the wearable electronic device 201 is not worn on the user's body. Thereafter, the wearable electronic device 201 may transmit a first message for displaying information indicating that the at least one function may be executed on the first external electronic device 202 in operation 319, based on determining that the wearable electronic device 201 is not worn on the user's body.

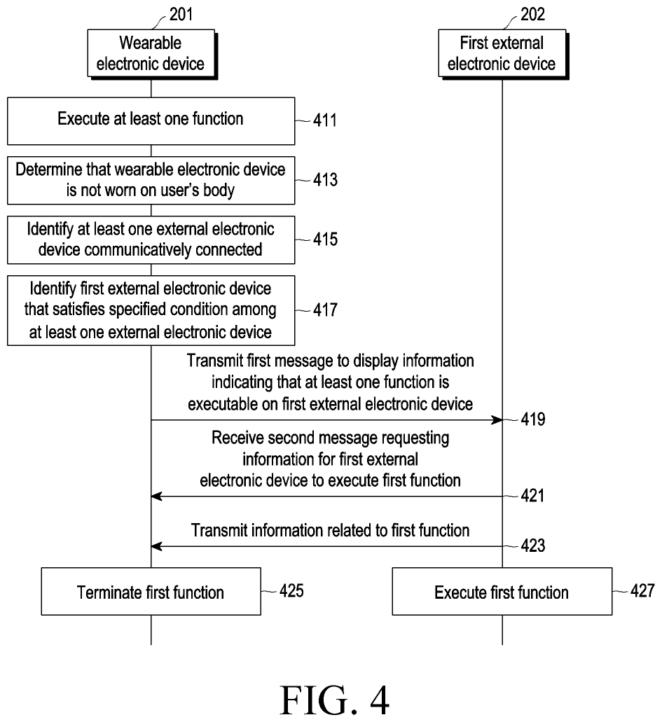

FIG. 4 is a view illustrating an operation of providing information related to a function being executed by the wearable electronic device to the first external electronic device according to an embodiment.

In the following embodiment, each operation may be sequentially performed, but is not necessarily performed sequentially. For example, the order of the operations may be changed, and at least two operations may be performed in parallel.

Referring to FIG. 4, according to an embodiment, in operation 411, the wearable electronic device 201 (e.g., the wearable electronic device 201 of FIG. 2B) may execute at least one function of the wearable electronic device 201. According to an embodiment, the at least one function may include a function related to at least one application of the wearable electronic device 201. For example, the at least one function may include a function related to audio recording, a function related to a call, a function related to exercise, a function related to a timer, a function related to playing content, a function related to a memo, or a function related to an output of a notification.

According to an embodiment, in operation 413, the wearable electronic device 201 may determine that the wearable electronic device 201 is not worn on the user's body through the sensor 230 (e.g., the sensor 230 of FIG. 2B).

According to an embodiment, in operation 415, based on confirming that the wearable electronic device 201 is not worn on the user's body, the wearable electronic device 201 may identify at least one external electronic device 202 or 203 (e.g., the first external electronic device 202 of FIG. 2B and the second external electronic device 203 of FIG. 2B) communicatively connected using a short-range communication technology through the communication circuitry 290 (e.g., the communication circuitry 290 of FIG. 2B). For example, the short-range communication technology may include Wi-Fi communication technology and Bluetooth low energy (BLE) communication technology.

According to an embodiment, the wearable electronic device 201 may request information about the at least one external electronic device 202 and 203 from at least one external electronic device 202 and 203. According to an embodiment, the at least one external electronic device 202 and 203 may transmit information about at least one external electronic device to the wearable electronic device 201 in response to the request.

According to an embodiment, the information related to the at least one external electronic device 202 and 203 may include at least one of information about the activated state of the at least one external electronic device 202 and 203, information about the number of user inputs input to the at least one external electronic device 202 and 203, or information about the type and wearing state of the at least one external electronic device 202 and 203. According to an embodiment, the activated state of the at least one external electronic device 202 and 203 may include a state in which the display of the at least one external electronic device 202 and 203 is turned on or a state in which the level of the battery of the at least one external electronic device 202 and 203 is higher than a specified level.

According to an embodiment, in operation 417, the wearable electronic device 201 may identify a first external electronic device 202 that satisfies the specified condition among the at least one external electronic device 202 and 203 based on the information related to the at least one external electronic device 202 and 203. For example, the specified condition may include a condition for a device capable of continuously executing at least one function being executed by the wearable electronic device 201.

According to an embodiment, in operation 419, the wearable electronic device 201 may transmit a first message to the first external electronic device 202 to allow the first external electronic device 202 to display, on the display 261 (e.g., the display 261 of FIG. 2B), information indicating that the at least one function may be executed on the first external electronic device 202. According to an embodiment, the first message may further include information that allows the first external electronic device 202 to display a notification (information) indicating that the at least one function is being executed on the wearable electronic device 201. According to an embodiment, the first external electronic device 202 may display information indicating that the at least one function may be executed on the first external electronic device 202.

According to an embodiment, in operation 421, the wearable electronic device 201 may receive, from the first external electronic device 202, a second message requesting information for the first external electronic device 202 to execute the first function from the first external electronic device 202. According to an embodiment, the first external electronic device 202 may transmit, to the wearable electronic device 201, a second message requesting information for the first external electronic device 202 to execute the first function based on identifying a user input for executing the first function among the at least one function.

According to an embodiment, in operation 423, the wearable electronic device 201 may transmit the information related to the first function to the first external electronic device 202. For example, the information related to the first function may include an application related to the first function, a time when the first function is executed, and information about the progress state of the first function.

According to an embodiment, in operation 425, the wearable electronic device 201 may terminate the first function based on transmitting the information related to the first function to the first external electronic device 202. According to the implementation, the wearable electronic device 201 may execute the first function (e.g., for a predetermined time) without terminating the first function.

According to an embodiment, in operation 427, the first external electronic device 202 may execute the first function based on receiving the information related to the first function. For example, the first external electronic device 202 may continuously execute the first function from the time when the first function is stopped in the wearable electronic device 201. For example, when the first function is a timer-related function, the first external electronic device 202 may continuously execute the first function (e.g., restart the timer from the time when the timer is stopped) based on the time when the timer is stopped in the wearable electronic device 201. For example, when the first function is a function related to playing content, the first external electronic device 202 may continuously execute the first function (e.g., play content from the time when it is stopped) based on the time when the playback of the content is stopped in the wearable electronic device 201.

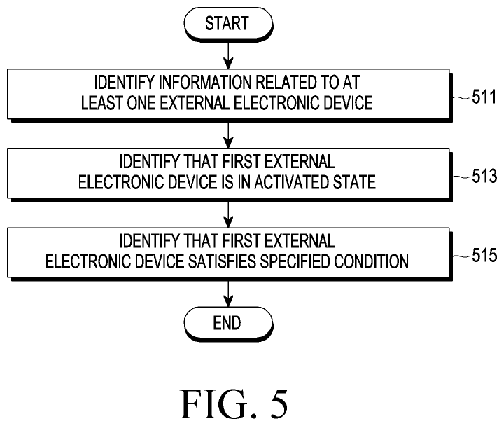

FIG. 5 is a flowchart illustrating an operation in which a wearable electronic device according to an embodiment identifies a device satisfying a specified condition among the at least one external electronic device.

In the following embodiment, each operation may be sequentially performed, but is not necessarily performed sequentially. For example, the order of the operations may be changed, and at least two operations may be performed in parallel.

Referring to FIG. 5, according to an embodiment, in operation 511, the wearable electronic device 201 (e.g., the wearable electronic device 201 of FIG. 2A and the wearable electronic device 201 of FIG. 2B) may identify the information related to the at least one external electronic device 202 and 203 (e.g., the first external electronic device 202 of FIGS. 2A and 2B, the second external electronic device 203 of FIGS. 2A and 2B) based on determining that the wearable electronic device 201 is not worn on the user's body while executing at least one function. For example, the information related to the at least one external electronic device 202 and 203 may include information indicating whether at least one external electronic device 202 and 203 is in the activated state. For example, the activated state may include a state in which the display of the at least one external electronic device 202 and 203 is turned on or a state in which the level of the battery of the at least one external electronic device 202 and 203 is higher than a specified level. For example, the specified level may represent the remaining amount of battery for executing at least one function being executed on the wearable electronic device 201.

According to an embodiment, in operation 513, the wearable electronic device 201 may identify that the first external electronic device 202 is in the activated state based on the information related to the at least one external electronic device 202 and 203. According to an embodiment, the wearable electronic device 201 may identify that the second external electronic device 203 is in a deactivated state based on the information related to the at least one external electronic device 202 and 203. According to an embodiment, the wearable electronic device 201 may identify that the first external electronic device 202 is in the activated state based on identifying that the display of the first external electronic device 202 is turned on or the battery level of the first external electronic device 202 is higher than a specified level.

According to an embodiment, in operation 515, the wearable electronic device 201 may identify that the first external electronic device 202 satisfies the specified condition based on identifying that the first external electronic device 202 is in the activated state.

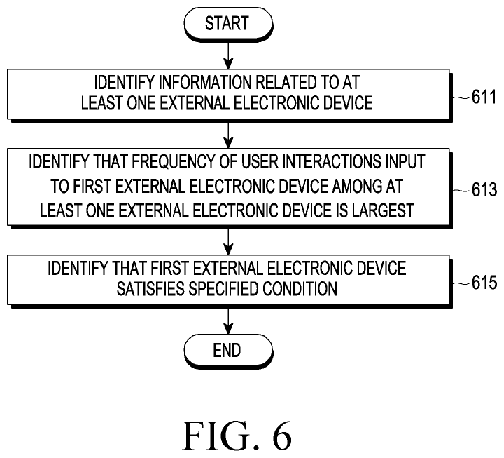

FIG. 6 is a flowchart illustrating an operation in which a wearable electronic device according to an embodiment identifies a device satisfying a specified condition among the at least one external electronic device.

In the following embodiment, each operation may be sequentially performed, but is not necessarily performed sequentially. For example, the order of the operations may be changed, and at least two operations may be performed in parallel.

Referring to FIG. 6, according to an embodiment, in operation 611, the wearable electronic device 201 (e.g., the wearable electronic device 201 of FIG. 2A and the wearable electronic device 201 of FIG. 2B) may identify the information related to the at least one external electronic device 202 and 203 (e.g., the first external electronic device 202 of FIGS. 2A and 2B, the second external electronic device 203 of FIGS. 2A and 2B) based on determining that the wearable electronic device 201 is not worn on the user's body while executing at least one function. For example, the information related to the at least one external electronic device 202 and 203 may include information indicating which electronic device the user currently preferentially uses. For example, the information related to the at least one external electronic device 202 and 203 may include information about the frequency of user interactions (or inputs) input to each of the at least one external electronic device 202 and 203 for a specified time. For example, the user interactions (or inputs) may include touch interactions (or inputs), long press interactions (or inputs), pinch interactions (or inputs), drag interactions (or inputs), tap interactions (or inputs), or swipe interactions (or inputs). However, this is an example, and the user interaction (or input) may not be limited to the example, but may include various interactions (or inputs).

According to an embodiment, in operation 613, the wearable electronic device 201 may identify that the frequency of user interaction input to the first external electronic device 202 among the at least one external electronic device 202 and 203 is the largest based on the information related to the at least one external electronic device 202 and 203. For example, the wearable electronic device 201 may identify the external electronic device with the largest number of user interactions (or inputs) identified for a specified time as the first external electronic device 202. For example, the wearable electronic device 201 may compare the frequency (or number) of user interactions (or inputs) input to the first external electronic device 202 identified for the specified time with the frequency (or number) of user interactions (or inputs) input to the second external electronic device 203 identified for the specified time. For example, based on identifying that the number of user interactions (or inputs) input to the first external electronic device 202 is larger than the frequency (or number) of user interactions (or inputs) input to the second external electronic device 203, it may be identified that the frequency (or number) of user interactions (or inputs) input to the first external electronic device 202 is larger than the second external electronic device 203.

According to an embodiment, the wearable electronic device 201 may compare the frequency (or number) of user interactions (or inputs) input to the first external electronic device 202 and the frequency (or number) of user interactions (or inputs) input to the second external electronic device 203 based on identifying that the at least one external electronic device 202 and 203 is in the activated state. The wearable electronic device 201 may identify an external electronic device (e.g., the first external electronic device 202) that is identified to have the largest frequency (or number) of user interactions (or inputs) among the at least one external electronic device 202 and 203 in the activated state as an external electronic device that satisfies the specified condition.

According to an embodiment, in operation 615, the wearable electronic device 201 may identify that the first external electronic device 202 satisfies the specified condition based on identifying that the frequency (or number) of user interactions (or inputs) input to the first external electronic device 202 is the largest.

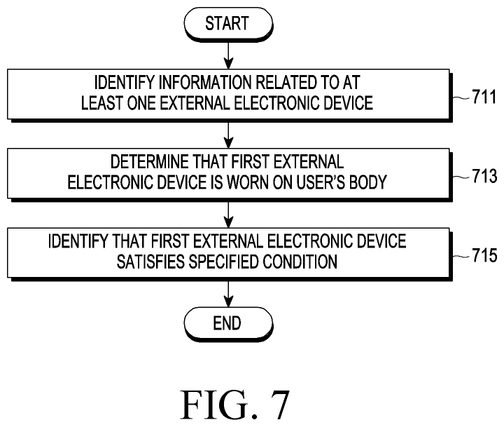

FIG. 7 is a flowchart illustrating an operation in which a wearable electronic device according to an embodiment identifies a device satisfying a specified condition among the at least one external electronic device.

In the following embodiment, each operation may be sequentially performed, but is not necessarily performed sequentially. For example, the order of the operations may be changed, and at least two operations may be performed in parallel.

Referring to FIG. 7, according to an embodiment, in operation 711, the wearable electronic device 201 (e.g., the wearable electronic device 201 of FIG. 2A and the wearable electronic device 201 of FIG. 2B) may identify the information related to the at least one external electronic device 202 and 203 (e.g., the first external electronic device 202 of FIGS. 2A and 2B, the second external electronic device 203 of FIGS. 2A and 2B) based on determining that the wearable electronic device 201 is not worn on the user's body while executing at least one function. For example, the information related to the at least one external electronic device 202 and 203 may include information about the type of the at least one external electronic device 202 and 203 and information indicating whether at least one external electronic device 202 and 203 is worn on the user's body.

According to an embodiment, in operation 713, the wearable electronic device 201 may determine that the first external electronic device 202 is worn on the user's body based on the information related to the at least one external electronic device 202 and 203. According to an embodiment, the first external electronic device 202 may include the wearable electronic device that may be worn on the user's body.

According to an embodiment, in operation 715, the wearable electronic device 201 may identify that the first external electronic device 202 satisfies the specified condition based on determining that the first external electronic device 202 is worn on the user's body.

According to an embodiment, the wearable electronic device 201 may identify that the first external electronic device 202 satisfies the specified condition based on determining that the first external electronic device 202 is worn on the user's body and is in the activated state.

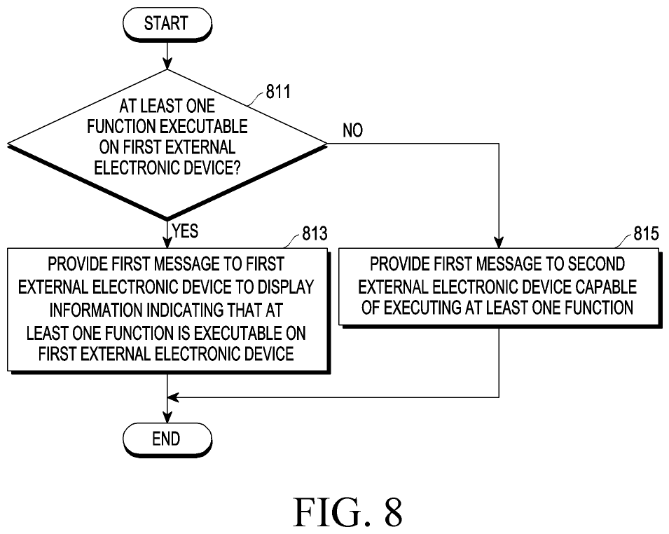

FIG. 8 is a flowchart illustrating an operation in which a wearable electronic device according to an embodiment identifies whether a first external electronic device satisfying a specified condition is a device capable of executing at least one function.

In the following embodiment, each operation may be sequentially performed, but is not necessarily performed sequentially. For example, the order of the operations may be changed, and at least two operations may be performed in parallel.

Referring to FIG. 8, according to an embodiment, in operation 811, the wearable electronic device 201 (e.g., the wearable electronic device 201 of FIG. 2A, the wearable electronic device 201 of FIG. 2B) may identify whether at least one function of the wearable electronic device 201 is executable on the first external electronic device 202 (e.g., the first external electronic device 202 of FIG. 2A, and the first external electronic device 202 of FIG. 2B) that satisfies the specified condition. According to an embodiment, when it is identified that the first external electronic device 202 does not include a hardware component or a software component required to execute at least one function, the wearable electronic device 201 may identify that at least one function is not executable on the first external electronic device 202.

For example, when it is identified that the at least one function is an audio recording function, and the first external electronic device 202 is a device that does not include a microphone (and speaker), the wearable electronic device 201 may identify that the at least one function is not executable on the first external electronic device 202. For example, when it is identified that the at least one function is related to a call, and the first external electronic device 202 is a device that does not include a speaker and a microphone, the wearable electronic device 201 may identify that the at least one function is not executable on the first external electronic device 202.

According to an embodiment, when it is identified that the at least one function is executable on the first external electronic device 202 (operation 811-Yes), in operation 813, the wearable electronic device 201 may provide the first message to the first external electronic device 202 to display information indicating that the at least one function is executable on the first external electronic device 202.

According to an embodiment, when it is identified that the at least one function is not executable on the first external electronic device 202 (operation 811-No), in operation 815, the wearable electronic device 201 may provide the first message to the second external electronic device 203 (e.g., the second external electronic device 203 of FIG. 2A or the second external electronic device 203 of FIG. 2B) capable of executing at least one function. For example, the second external electronic device 203 may be a device connected to the wearable electronic device 201 using short-range communication technology, or may include a device connected to the server 204 using the same authentication information as the authentication information specified in the wearable electronic device 201 through the server 204 (e.g., the server 204 of FIG. 2B).

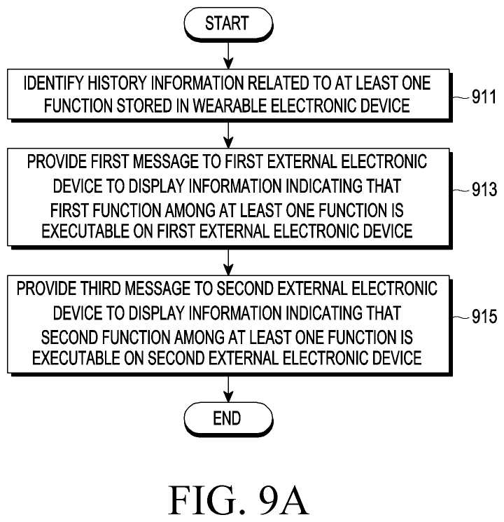

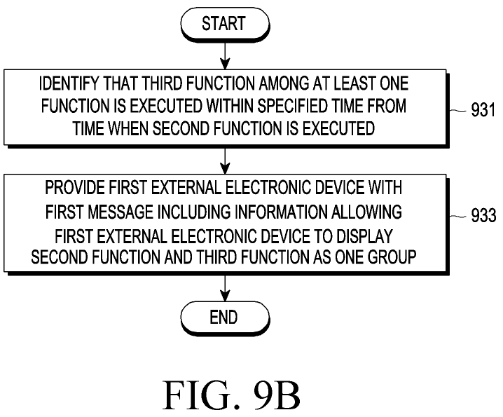

FIG. 9A is a flowchart illustrating an operation in which a wearable electronic device according to an embodiment identifies a device capable of executing a function of the wearable electronic device based on history information.

In the following embodiment, each operation may be sequentially performed, but is not necessarily performed sequentially. For example, the order of the operations may be changed, and at least two operations may be performed in parallel.

Referring to FIG. 9A, according to an embodiment, in operation 911, the wearable electronic device 201 (e.g., the wearable electronic device 201 of FIG. 2A or the wearable electronic device 201 of FIG. 2B) may identify history information related to at least one function stored in the wearable electronic device 201. For example, the first external electronic device 202 (e.g., the first external electronic device 202 of FIG. 2A, the first external electronic device 202 of FIG. 2B), and the second external electronic device 203 (e.g., the second external electronic device 203 of FIG. 2A, the second external electronic device 203 of FIG. 2B) may be devices connected to the wearable electronic device 201 using short-range communication technology, or may include a device connected to the server 204 using the same authentication information as the authentication information specified in the wearable electronic device 201 through the server 204 (e.g., the server 204 of FIG. 2B). According to an embodiment, the history information may include information about at least one of the frequency at which at least one function being executed on the wearable electronic device 201 is continuously executed by at least one external electronic device, the frequency for a specific time when the function is continuously executed by at least one external electronic device, or the frequency for a specific location where the function is continuously executed by at least one external electronic device.

According to an embodiment, the frequency at which at least one function being executed on the wearable electronic device 201 is continuously executed by the at least one external electronic device may include the number of times that at least one external electronic device continuously executes at least one function being executed on the wearable electronic device 201. For example, the wearable electronic device 201 may display a list including external electronic devices capable of continuously executing the first function being executed on the wearable electronic device 201. When a user input to the first external electronic device 202 among the external electronic devices included in the list is identified, the wearable electronic device 201 may provide a command for the first external electronic device 202 to continuously execute a function corresponding to the first function to the first external electronic device 202. The first external electronic device 202 may continuously execute the function corresponding to the first function based on the command. For example, the number of times that at least one external electronic device continuously executes at least one function being executed on the wearable electronic device 201 may indicate the number of user inputs (interactions) for selecting any one external electronic device from the list including external electronic devices capable of continuously executing at least one function being executed on the wearable electronic device 201. According to an embodiment, the frequency for the location where at least one function being executed on the wearable electronic device 201 is continuously executed by at least one external electronic device may include the frequency (number of times) for a specific location (e.g., a place) where at least one external electronic device continuously executes at least one function being executed on the wearable electronic device 201.

The time when it is continuously executed by the at least one external electronic device may include the frequency (number of times) for the time when the at least one external electronic device continuously executes at least one function being executed on the wearable electronic device 201.

According to an embodiment, in operation 915, the wearable electronic device 201 may provide a third message to the second external electronic device 203 to display information indicating that the second function of at least one function is executable on the second external electronic device 203 based on the history information.

For example, the wearable electronic device 201 may provide the first message to the first external electronic device 202 with the highest frequency of continuously executing the first function among the at least one external electronic device based on history information.

For example, the wearable electronic device 201 may provide the first message to the first external electronic device 202 with the highest frequency of continuously executing the first function at the current location identified by the wearable electronic device 201 based on history information.

For example, the wearable electronic device 201 may provide the first message to the first external electronic device 202 with the highest frequency of continuously executing the first function at the current time identified by the wearable electronic device 201 based on the history information.

According to an embodiment, in operation 915, the wearable electronic device 201 may provide a third message to the second external electronic device 203 to display information indicating that the second function of at least one function is executable on the second external electronic device 203 based on the history information.

For example, the wearable electronic device 201 may provide the third message to the second external electronic device 203 with the highest frequency of continuously executing the second function among the at least one external electronic device based on the history information.

For example, the wearable electronic device 201 may provide the third message to the first external electronic device 202 with the highest frequency of continuously executing the second function at the current location identified by the wearable electronic device 201 based on history information.

For example, the wearable electronic device 201 may provide the third message to the first external electronic device 202 with the highest frequency of continuously executing the second function at the current time identified by the wearable electronic device 201 based on the history information.

FIG. 9B is a flowchart illustrating an operation of transmitting a message for displaying information about a second function and a third function as one group by a wearable electronic device according to an embodiment.

In the following embodiment, each operation may be sequentially performed, but is not necessarily performed sequentially. For example, the order of the operations may be changed, and at least two operations may be performed in parallel.

Referring to FIG. 9B, according to an embodiment, in operation 933, the wearable electronic device 201 (e.g., the wearable electronic device 201 of FIG. 2A, the wearable electronic device 201 of FIG. 2B) may identify that the third function among the at least one function being executed by the wearable electronic device 201 is executed within a specified time (e.g., within 1 minute) from the time when the second function among the at least one function is executed.

According to an embodiment, in operation 933, the wearable electronic device 201 may transmit a first message including information for allowing the first external electronic device 202 (e.g., the first external electronic device 202 of FIG. 2A or the first external electronic device 202 of FIG. 2B) that satisfies the specified condition to display the second function and the third function as one group to the first external electronic device 202.

According to an embodiment, the first external electronic device 202 may display the second function and the third function as one group based on the first message. According to an embodiment, the first external electronic device 202 may display information indicating that the second function and the third function are executable at the same time.

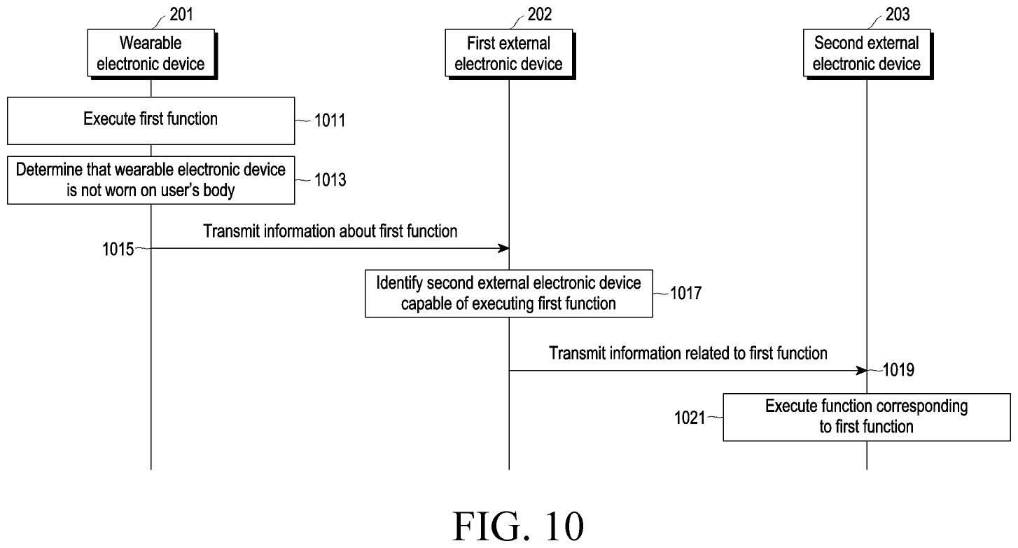

FIG. 10 is a flowchart illustrating an operation in which a wearable electronic device according to an embodiment transmits information about a first function.

In the following embodiment, each operation may be sequentially performed, but is not necessarily performed sequentially. For example, the order of the operations may be changed, and at least two operations may be performed in parallel.

Referring to FIG. 10, according to an embodiment, in operation 1011, the wearable electronic device 201 (e.g., the wearable electronic device 201 of FIG. 2A or the wearable electronic device 201 of FIG. 2B) may execute at least one function.

According to an embodiment, in operation 1013, the wearable electronic device 201 may determine that the wearable electronic device 201 is not worn on the user's body through the sensor 230 (e.g., the sensor 230 of FIG. 2A) while executing at least one function.

According to an embodiment, in operation 1015, the wearable electronic device 201 may transmit information about the first function to the first external electronic device 202 (e.g., the first external electronic device 202 of FIG. 2B) communicatively connected to the wearable electronic device 201 based on determining that the wearable electronic device 201 is not worn on the user's body. Alternatively, the wearable electronic device 201 may receive a message requesting information about the first function for executing the first function from the first external electronic device 202. The wearable electronic device 201 may provide information about the first function to the first external electronic device 202 based on receiving a message requesting information about the first function from the first external electronic device 202.

According to an embodiment, in operation 1017, the first external electronic device 202 may identify the second external electronic device 203 (e.g., the second external electronic device 203 of FIG. 2B) capable of executing the first function. For example, the second external electronic device 203 may include a device communicatively connected to the first external electronic device 202. According to an embodiment, the first external electronic device 202 may display information indicating that the second external electronic device 203 may execute the function corresponding to the first function through the display 261 (e.g., the display 261 of FIG. 2B). According to an embodiment, the first external electronic device 202 may display information indicating that the first external electronic device 202 may execute the function corresponding to the first function through the display 261.

According to an embodiment, in operation 1019, when a user input for allowing the second external electronic device 203 to execute the function corresponding to the first function is identified, the first external electronic device 202 may provide the information related to the first function to the second external electronic device 203.

According to an embodiment, in operation 1021, the second external electronic device 203 may continuously execute the function corresponding to the first function based on receiving the information related to the first function. According to an embodiment, the wearable electronic device 201 may stop executing the first function.

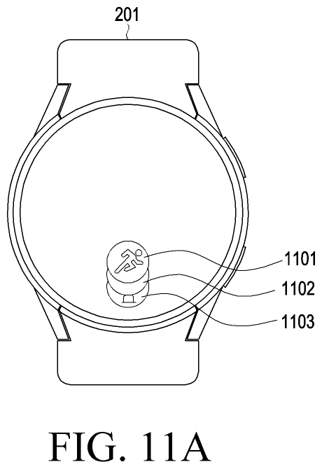

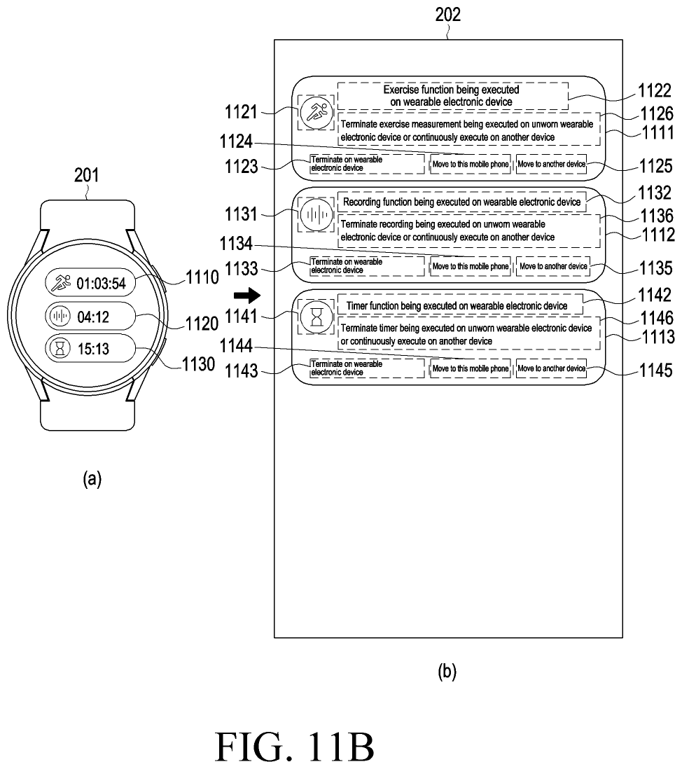

FIG. 11A is a view illustrating a home screen of a wearable electronic device according to an embodiment.

Referring to FIG. 11A, the wearable electronic device 201 (e.g., the wearable electronic device 201 of FIG. 2A or the wearable electronic device 201 of FIG. 2B) may execute a plurality of functions. For example, the plurality of functions may include a function related to exercise, a function related to audio recording, and a function related to a timer.

According to an embodiment, FIG. 11A is described under the assumption that the wearable electronic device 201 simultaneously executes a plurality of functions of the wearable electronic device 201. According to an embodiment, at least some of the plurality of functions of the wearable electronic device 201 may be omitted or replaced with functions different from the plurality of functions of the wearable electronic device 201. According to an embodiment, the wearable electronic device 201 may display an icon (or thumbnail, image) pre-specified for each of the functions being executed so that the user may visually distinguish each function of the wearable electronic device 201.

According to an embodiment, the wearable electronic device 201 may display an icon (or thumbnail or image) specified for each of the plurality of functions being executed on the home screen (or lock screen) of the wearable electronic device 201. For example, the wearable electronic device 201 may display an icon 1101 corresponding to the function related to exercise, an icon 1102 corresponding to the function related to audio recording, and an icon 1103 corresponding to the function related to a timer. For example, the wearable electronic device 201 may display the icon 1101 corresponding to the function related to exercise, the icon 1102 corresponding to the function related to audio recording, and the icon 1103 corresponding to the function related to the timer in different areas, respectively, of the display or superpose and display them, or merge them as if they overlap each other to display them as one icon. FIG. 11B is a view illustrating an operation in which a wearable electronic device according to an embodiment transmits information about a plurality of functions being executed by the wearable electronic device to a first external electronic device according to an embodiment. Referring to (a) of FIG. 11B, according to an embodiment, the wearable electronic device 201 (e.g., the wearable electronic device 201 of FIG. 2A or the wearable electronic device 201 of FIG. 2B) may execute the plurality of functions. For example, the plurality of functions may include a function related to exercise, a function related to audio recording, and a function related to a timer.

According to an embodiment, FIG. 11B is described under the assumption that the wearable electronic device 201 simultaneously executes the plurality of functions of the wearable electronic device 201. According to an embodiment, at least some of the plurality of functions of the wearable electronic device 201 may be omitted or replaced with functions different from the plurality of functions of the wearable electronic device 201. According to an embodiment, the wearable electronic device 201 may display an icon (or thumbnail, image) pre-specified for each of the functions being executed so that the user may visually distinguish each function of the wearable electronic device 201.

According to an embodiment, when a user input for selecting any one of the icon 1101 (e.g., 1101 of FIG. 11A) corresponding to the exercise-related function, the icon 1102 (e.g., 1102 of FIG. 11A) corresponding to the audio recording-related function, and the icon 1103 (e.g., 1103 of FIG. 11A) corresponding to the timer-related function is identified, the wearable electronic device 201 may display information 1110 indicating that the exercise-related function is being executed, information 1120 indicating that the audio recording-related function is being executed, and information 1130 indicating that the timer-related function is being executed.

According to an embodiment, the wearable electronic device 201 may display the information 1110 indicating that the exercise-related function is being executed, the information 1120 indicating that the audio recording-related function is being executed, and the information 1130 indicating that the timer-related function is being executed.

For example, the information 1110 indicating that the exercise-related function is being executed, the information 1120 indicating that the audio recording-related function is being executed, and the information 1130 indicating that the timer-related function is being executed may include information about the time when each of the plurality of functions is executed on the wearable electronic device 201.

According to an embodiment, the wearable electronic device 201 may transmit a first message to the first external electronic device 202 (e.g., the first external electronic device 202 of FIG. 2A or the first external electronic device 202 of FIG. 2B) to display information indicating that the plurality of functions are executable on the first external electronic device 202.

Referring to (b) of FIG. 11B, according to an embodiment, the first external electronic device 202 may display the information 1111, 1112, and 1113 indicating that the plurality of functions are executable on the first external electronic device 202 based on receiving a first message or a signal (command) related to the unwearing of the wearable electronic device 201 from the wearable electronic device 201. According to an embodiment, the first external electronic device 202 may display an object (e.g., move to this mobile phone) corresponding to the corresponding information.

According to an embodiment, the first external electronic device 202 may further display information indicating that the plurality of functions being executed on the wearable electronic device 201 may be terminated without executing the plurality of functions on the first external electronic device 202. According to an embodiment, the first external electronic device 202 may further display an object (e.g., terminate on the wearable electronic device 201) corresponding to the corresponding information.

According to an embodiment, the first external electronic device 202 may further display information indicating that the plurality of functions being executed on the wearable electronic device 201 are executable on another external electronic device. According to an embodiment, the first external electronic device 202 may further display an object (e.g., move to another device) corresponding to the corresponding information.

According to an embodiment, the first external electronic device 202 may display the information 1111 indicating that the function related to an exercise is executable based on receiving a first message or a signal (command) related to the unwearing of the wearable electronic device 201 from the wearable electronic device 201. For example, the first external electronic device 202 may display a specified text 1122 (e.g., exercise function being executed on the wearable electronic device) indicating the function being executed on the wearable electronic device 201. For example, the first external electronic device 202 may display a specified icon 1121 (or an image or thumbnail) indicating the function related to exercise. For example, the first external electronic device 202 may display a text 1126 indicating that the function being executed on the wearable electronic device 201 is continuously executable on the first external electronic device 202 or at least one external electronic device identified by the first external electronic device 202. The first external electronic device 202 may further display an object 1123 (e.g., terminate on the wearable electronic device 201) indicating that the exercise-related function being executed on the wearable electronic device 201 may be terminated without executing the exercise-related function on the first external electronic device 202, an object 1124 (e.g., move to this mobile phone) indicating that the exercise-related function is executable on the first external electronic device 202, and an object 1125 (e.g., move to another device) indicating that the exercise-related function is executable on another external electronic device. If a user input for selecting any one of the object 1123 indicating that the exercise-related function being executed on the wearable electronic device 201 may be terminated, the object 1124 indicating that the exercise-related function is executable on the first external electronic device 202, or the object 1125 indicating that the exercise-related function is executable on another external electronic device is identified, the first external electronic device 202 may provide a command for terminating the exercise-related function being executed on the wearable electronic device 201 to the wearable electronic device 201. According to an embodiment, the wearable electronic device 201 may terminate the exercise-related function being executed on the wearable electronic device 201 based on receiving the command.

According to an embodiment, the first external electronic device 202 may display the information 1112 indicating that the audio recording-related function is executable based on receiving a first message or a signal (command) related to the unwearing of the wearable electronic device 201 from the wearable electronic device 201. For example, the first external electronic device 202 may display a specified text 1132 (e.g., recording function being executed on the wearable electronic device) indicating the function being executed on the wearable electronic device 201. For example, the first external electronic device 202 may display a specified icon 1131 (or an image or thumbnail) indicating the recording-related function. For example, the first external electronic device 202 may display a text 1136 indicating that the function being executed on the wearable electronic device 201 is continuously executable on the first external electronic device 202 or at least one external electronic device identified by the first external electronic device 202. The first external electronic device 202 may display an object 1133 (e.g., terminate on the wearable electronic device 201) indicating that the audio recording-related function being executed on the wearable electronic device 201 may be terminated without executing the audio recording-related function on the first external electronic device 202, an object 1134 (e.g., move to this mobile phone) indicating that the audio recording-related function is executable on the first external electronic device 202, and an object 1135 (e.g., move to another device) indicating that the audio recording-related function is executable on another external electronic device. If a user input for selecting any one of the object 1133 indicating that the audio recording-related function being executed on the wearable electronic device 201 may be terminated, the object 1134 indicating that the audio recording-related function is executable on the first external electronic device 202, or the object 1135 indicating that the audio recording-related function is executable on another external electronic device is identified, the first external electronic device 202 may provide a command for terminating the audio recording-related function being executed on the wearable electronic device 201 to the wearable electronic device 201. According to an embodiment, the wearable electronic device 201 may terminate the audio recording-related function being executed on the wearable electronic device 201 based on receiving the command.

According to an embodiment, the first external electronic device 202 may display the information 1113 indicating that the timer-related function is executable based on receiving a first message or a signal (command) related to the unwearing of the wearable electronic device 201 from the wearable electronic device 201. For example, the first external electronic device 202 may display a specified text 1132 (e.g., timer function being executed on the wearable electronic device) indicating the function being executed on the wearable electronic device 201. For example, the first external electronic device 202 may display a specified icon 1141 (or an image or thumbnail) indicating the timer-related function. For example, the first external electronic device 202 may display a text 1146 indicating that the function being executed on the wearable electronic device 201 is continuously executable on the first external electronic device 202 or at least one external electronic device identified by the first external electronic device 202. The first external electronic device 202 may display an object 1143 (e.g., terminate on the wearable electronic device 201) indicating that the timer-related function being executed on the wearable electronic device 201 may be terminated without executing the timer-related function on the first external electronic device 202, an object 1144 (e.g., move to this mobile phone) indicating that the timer-related function is executable on the first external electronic device 202, and an object 1145 (e.g., move to another device) indicating that the timer-related function is executable on another external electronic device. If a user input for selecting any one of the object 1133 indicating that the timer-related function being executed on the wearable electronic device 201 may be terminated, the object 1134 indicating that the timer-related function is executable on the first external electronic device 202, or the object 1135 indicating that the timer-related function is executable on another external electronic device is identified, the first external electronic device 202 may provide a command for terminating the timer-related function being executed on the wearable electronic device 201 to the wearable electronic device 201. According to an embodiment, the wearable electronic device 201 may terminate the timer-related function being executed on the wearable electronic device 201 based on receiving the command.

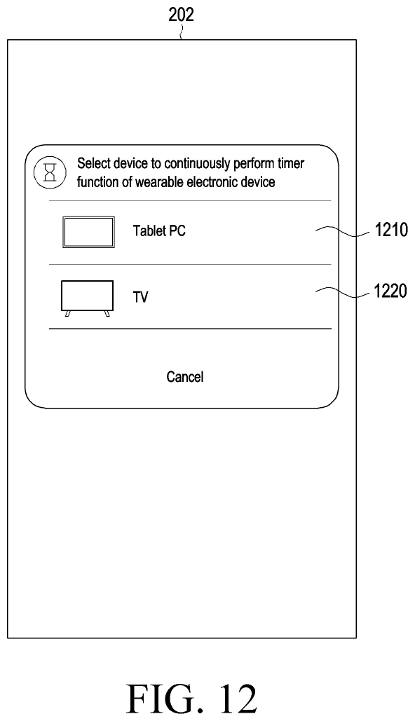

FIG. 12 is a view illustrating an operation in which a first external electronic device according to an embodiment displays information about devices capable of executing a function related to a timer among a plurality of functions according to an embodiment.

Referring to FIG. 12, according to an embodiment, the first external electronic device 202 (e.g., the first external electronic device 202 of FIG. 2A, the first external electronic device 202 of FIG. 2B) may display the information about an external electronic device capable of executing the timer-related function based on identifying a user input for an object (e.g., moving to another device of 1111 of FIG. 11) indicating that the timer-related function is executable on another external electronic device. For example, the external electronic device capable of executing the timer-related function may include a device connected to the server 204 (e.g., the server 204 of FIG. 2A) using the same authentication information as the authentication information specified in the wearable electronic device 201 (e.g., the wearable electronic device 201 of FIG. 2A) or a device connected to the wearable electronic device 201 and/or the first external electronic device 202 using short-range communication technology through the communication circuitry 290, 291 (e.g., the communication circuitry 290, 291 of FIG. 2B).

According to an embodiment, when a user input for selecting an object 1210 (e.g., a tablet PC) for an external electronic device capable of executing the timer-related function is identified, the first external electronic device 202 may transmit information about the timer-related function to the external electronic device so that the corresponding external electronic device (e.g., a tablet PC) may execute the timer-related function.

According to an embodiment, when a user input for selecting an object 1220 (e.g., a TV) for an external electronic device capable of executing the timer-related function is identified, the first external electronic device 202 may transmit information about the timer-related function to the external electronic device so that the corresponding external electronic device (e.g., a TV) may execute the timer-related function.

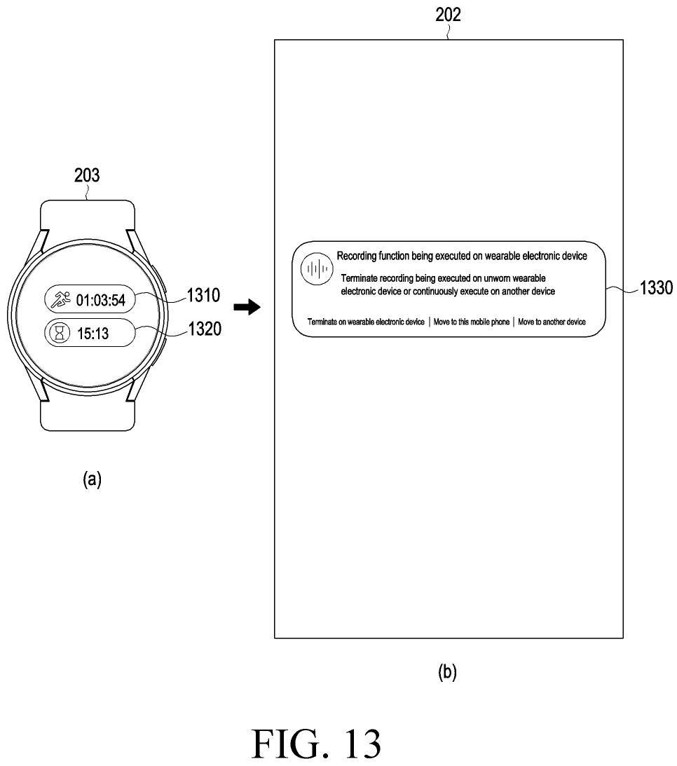

FIG. 13 is a view illustrating an operation of displaying information about functions executable on a first external electronic device and a second external electronic device according to an embodiment.

Referring to (a) of FIG. 13, according to an embodiment, the wearable electronic device 201 (e.g., the wearable electronic device 201 of FIG. 2A, the wearable electronic device 201 of FIG. 2B) may identify the second external electronic device 203 (e.g., the second external electronic device 203 of FIG. 2A, the second external electronic device 203 of FIG. 2B) that is determined to be worn on the user's body and is in the activated state.

According to an embodiment, the wearable electronic device 201 (e.g., the wearable electronic device 201 of FIG. 2A, the wearable electronic device 201 of FIG. 2B) may transmit information related to the functions to the second external electronic device 203 so that the second external electronic device 203 executes the functions (e.g., the exercise-related function, the timer-related function) among the plurality of functions (e.g., the exercise-related function, the timer-related function, and the audio recording-related function) being executed.

According to an embodiment, the second external electronic device 203 may execute the corresponding functions based on receiving the information related to the functions. According to an embodiment, the second external electronic device 203 may display the information 1310 and 1320 about the functions being executed by the second external electronic device 203.

Referring to (b) of FIG. 13, according to an embodiment, the wearable electronic device 201 may transmit, to the first external electronic device 202 (e.g., the first external electronic device 202 of FIG. 2A, the first external electronic device 202 of FIG. 2B), a message indicating that the first external electronic device 202 (e.g., the first external electronic device 202 of FIG. 2A, the first external electronic device 202 of FIG. 2B) in the activated state may execute the remaining function (e.g., the audio recording-related function) being executed by the wearable electronic device 201.

According to an embodiment, the first external electronic device 202 may display information 1330 about the corresponding function (e.g., the audio recording-related function) based on receiving the message indicating that it may execute the remaining function (e.g., the audio recording-related function) being executed by the wearable electronic device 201.

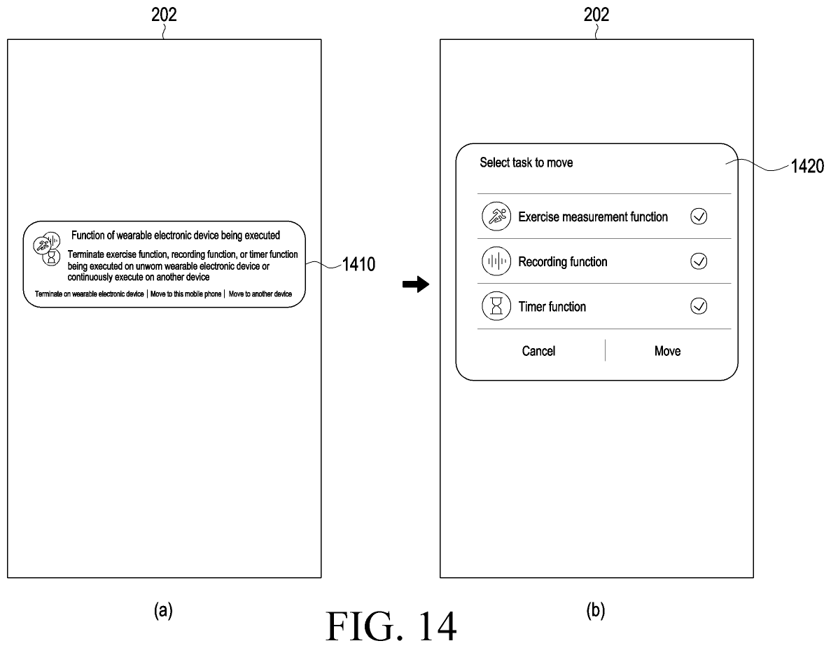

FIG. 14 is a view illustrating an operation in which a first external electronic device according to an embodiment displays information about functions being executed on a wearable electronic device 201 as one group.

Referring to (a) of FIG. 14, according to an embodiment, the wearable electronic device 201 (e.g., the wearable electronic device 201 of FIG. 2A, the wearable electronic device 201 of FIG. 2B) may transmit a message to the first external electronic device 202 to display information indicating that the first external electronic device 202 may execute a plurality of functions when identifying the first external electronic device 202 (e.g., the first external electronic device 202 of FIG. 2A, the first external electronic device 202 of FIG. 2B) satisfying a designated condition while executing a plurality of functions.

According to an embodiment, the first external electronic device 202 may display information about the plurality of functions as one group 1410.

According to an embodiment, the first external electronic device 202 may display an object (e.g., terminating all functions on the wearable electronic device 201) for terminating the execution of the plurality of functions on the wearable electronic device 201 without executing the plurality of functions on the first external electronic device 202.

According to an embodiment, the first external electronic device 202 may display an object (e.g., move to this mobile phone) for executing the plurality of functions on the first external electronic device 202.

According to an embodiment, the first external electronic device 202 may display an object (e.g., move to another device) for executing the plurality of functions on a device connected to the server 204 (e.g., the server 204 of FIG. 2A) using the same authentication information as the authentication information specified in the wearable electronic device 201 and a device connected to the wearable electronic device 201 and/or the first external electronic device 202 using a short-range communication technology through the communication circuitry 290, 291 (e.g., the communication circuitry 290, 291 of FIG. 2B).

Referring to (b) of FIG. 14, according to an embodiment, when a user input for the object (e.g., move to this mobile phone) for executing the plurality of functions on the first external electronic device 202 is identified, the first external electronic device 202 may display a screen 1420 for selecting at least one of the plurality of functions to be executed on the first external electronic device 202.

According to an embodiment, when a user input for at least one of the plurality of functions included in the screen 1420 is identified, the first external electronic device 202 may execute the function for which the user input has been identified on the first external electronic device 202.

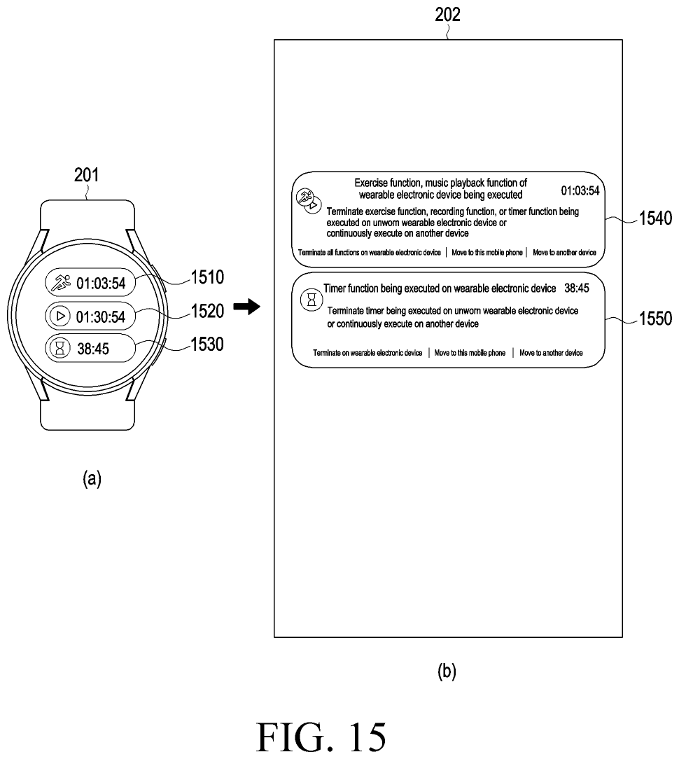

FIG. 15 is a view illustrating an operation in which a first external electronic device according to an embodiment displays information about functions executed at the same time on a wearable electronic device as one group.

Referring to (a) of FIG. 15, according to an embodiment, the wearable electronic device 201 (e.g., the wearable electronic device 201 of FIG. 2A or the wearable electronic device 201 of FIG. 2B) may display the information 1510, 1520, and 1530 about the functions being executed. According to an embodiment, the information 1510, 1520, and 1530 about the functions being executed may include a total time of the functions executed on the wearable electronic device 201, and information about the type of functions.

According to an embodiment, based on identifying that the exercise-related function and the content playback-related function are executed at the same time, the wearable electronic device 201 may transmit, to the first external electronic device 202, a message for displaying, as one group, the exercise-related function and the content playback-related function and information indicating that the first external electronic device 202 (e.g., the first external electronic device 202 of FIG. 2A, the first external electronic device 202 of FIG. 2B) may execute the exercise-related function and the content playback-related function. According to an embodiment, the wearable electronic device 201 may transmit, to the first external electronic device 202, a message for displaying information indicating that the first external electronic device 202 may execute the timer-related function.

Referring to (b) of FIG. 15, according to an embodiment, based on receiving the message for displaying the exercise-related function and the content playback-related function as one group, the first external electronic device 202 may display information 1540 indicating that the exercise-related function and the content playback-related function are executable as one group.

According to an embodiment, based on displaying the information 1540 indicating that the exercise-related function and the content playback-related function are executable as one group, the first external electronic device 202 may display the object (e.g., terminating all) for terminating the exercise-related function and the content playback-related function on the wearable electronic device 201 without executing them on the first external electronic device 202.

According to an embodiment, based on displaying the information 1540 indicating that the exercise-related function and the content playback-related function are executable as one group, the first external electronic device 202 may display an object (e.g., move to this mobile phone) for executing the exercise-related function and the content playback-related function on the first external electronic device 202.

According to an embodiment, based on displaying the information 1540 indicating that the exercise-related function and the content playback-related function are executable as one group, the first external electronic device 202 may display the object (e.g., move to another device) for executing the exercise-related function and the content playback-related function on another external electronic device.

According to an embodiment, based on receiving the message for displaying the information indicating that the timer-related function is executable, the first external electronic device 202 may display the information 1550 indicating that the timer-related function is executable.

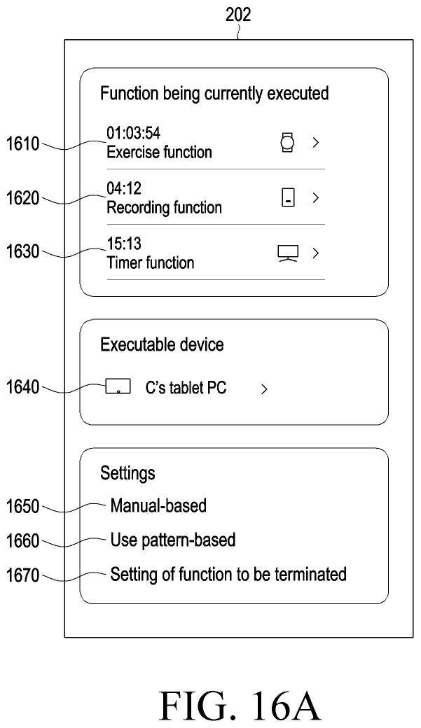

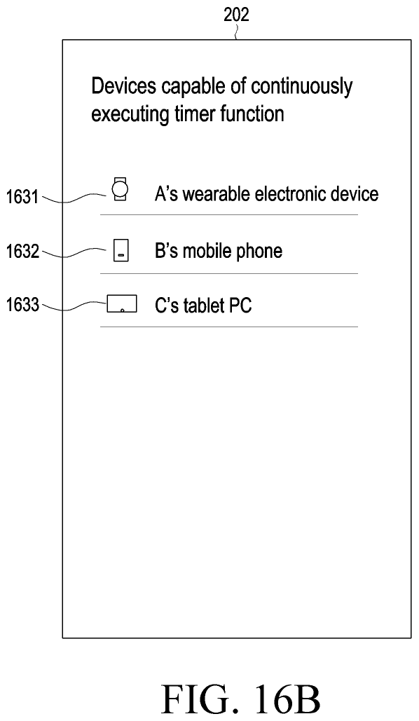

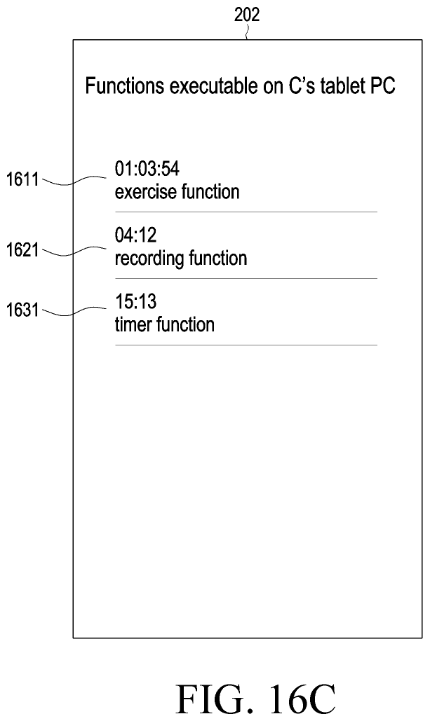

FIG. 16A is a view illustrating a setting screen of a first external electronic device according to an embodiment.

Referring to FIG. 16A, according to an embodiment, the first external electronic device 202 (e.g., the first external electronic device 202 of FIG. 2A, the first external electronic device 202 of FIG. 2B) may be connected to the server 204 (e.g., the server 204 of FIG. 2B) using the same authentication information as the authentication information specified in the wearable electronic device 201 (e.g., the wearable electronic device 201 of FIG. 2A, the wearable electronic device 201 of FIG. 2B).

According to an embodiment, the first external electronic device 202 may display information 1610, 1620, and 1630 about the plurality of first functions being currently executed on the wearable electronic device 201 and information 1640 about the device capable of executing at least one among the plurality of first functions by the devices connected to the server 204 using the same authentication information as the authentication information specified in the wearable electronic device 201.

According to an embodiment, the first external electronic device 202 may display the object 1650 (e.g., manual-based) for configuring it to execute at least one function based on a user input for executing at least one function executable by the first external electronic device 202. For example, the first external electronic device 202 may identify a user input for the object 1650. Thereafter, when a user input for the first external electronic device 202 to execute at least one function is identified, the first external electronic device 202 may provide a message for requesting information related to the at least one function to the wearable electronic device 201. The first external electronic device 202 may receive the information related to at least one function for executing the at least one function from the wearable electronic device 201.

According to an embodiment, the first external electronic device 202 may display the object 1660 for configuring the first external electronic device 202 to execute at least one executable function based on the history information stored in the wearable electronic device 201. For example, the first external electronic device 202 may identify a user input for the object 1660. Thereafter, the first external electronic device 202 may receive the information related to at least one function for executing the at least one function from the wearable electronic device 201 based on the history information stored in the wearable electronic device 201.

According to an embodiment, the first external electronic device 202 may display the object 1670 for setting to terminate the function being executed on the first external electronic device 202 when the level of the battery of the first external electronic device 202 is smaller than a specified level. For example, when a user input for the object 1660 is identified, the first external electronic device 202 may display a screen for setting at least one function to be terminated when the level of the battery of the first external electronic device 202 is smaller than the specified level among the plurality of functions. When at least one function to be terminated when the level of the battery of the first external electronic device 202 is smaller than the specified level is set, the at least one function may be automatically terminated when the level of the battery of the first external electronic device 202 is smaller than the specified level. For example, the specified level may indicate the remaining battery level required to execute at least one function. The designated level may be set by the user or may be automatically set by the first external electronic device 202.

FIG. 16B is a view illustrating an operation in which a first external electronic device according to an embodiment displays information about a device capable of executing a function being executed on a wearable electronic device.

Referring to FIG. 16B, according to an embodiment, the first external electronic device 202 (e.g., the first external electronic device 202 of FIG. 2A, the first external electronic device 202 of FIG. 2B) may identify a user input for selecting an object (e.g., 1630 of FIG. 16A) corresponding to information about the timer function among objects 1610, 1620, and 1630 corresponding to the information about the plurality of first functions.

According to an embodiment, the first external electronic device 202 may display the objects 1631, 1632, and 1633 for the devices capable of executing the timer-related function among the devices connected to the server 204 (e.g., the server 204 of FIG. 2B) using the same authentication information as the authentication information specified in the wearable electronic device 201 (e.g., the wearable electronic device 201 of FIG. 2A, the wearable electronic device 201 of FIG. 2B) or communicatively connected to the wearable electronic device 201 and/or the first external electronic device 202 using short-range communication technology.

According to an embodiment, based on identifying a user input for selecting any one of the objects 1631, 1632, and 1633 for the devices capable of executing the timer-related function, the first external electronic device 202 may provide the device for which the user input has been identified with information about the timer-related function so that the device for which the user input has been identified may execute the timer-related function.

FIG. 16C is a view illustrating an operation in which a first external electronic device according to an embodiment displays information about a function executable on a second external electronic device.

Referring to FIG. 16C, according to an embodiment, when a user input for the object (e.g., 1640 of FIG. 16A) for the device (e.g., tablet PC of C) capable of executing at least one function among the plurality of first functions being executed on the wearable electronic device 201 (e.g., the wearable electronic device 201 of FIG. 2A, the wearable electronic device 201 of FIG. 2B) is identified, the first external electronic device 202 (e.g., the first external electronic device 202 of FIG. 2A, the first external electronic device 202 of FIG. 2B) may display the objects 1611, 1621, and 1631 for the at least one function executable on the corresponding device.

According to an embodiment, when a user input for any one of the objects 1611, 1621, and 1631 for the at least one function is identified, the first external electronic device 202 may provide information related to the function corresponding to the object for which the user input has been identified to the corresponding device (e.g., tablet PC of C) to execute the function corresponding to the object for which the user input has been identified.

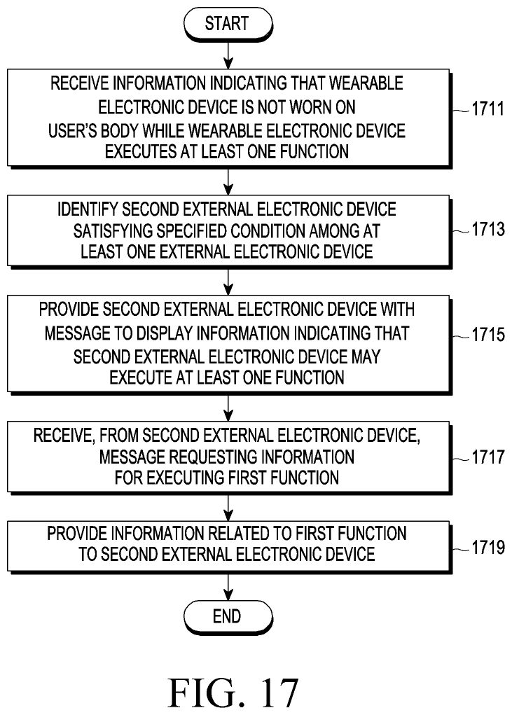

FIG. 17 is a flowchart illustrating an operation in which a first external electronic device according to an embodiment transmits information related to a function to a second external electronic device capable of executing a function being executed on a wearable electronic device.

Referring to FIG. 17, according to an embodiment, the first external electronic device 202 (e.g., the first external electronic device 202 of FIG. 2A, the first external electronic device 202 of FIG. 2B) and the second external electronic device 203 (e.g., the second external electronic device 203 of FIG. 2A, the second external electronic device 203 of FIG. 2B) may be connected to the server 204 (e.g., the server 204 of FIG. 2B) using the same authentication information as the authentication information specified in the wearable electronic device 201 (e.g., the wearable electronic device 201 of FIG. 2A, the wearable electronic device 201 of FIG. 2B) or connected to the wearable electronic device 201 using short-range communication technology through the communication circuitry 291 (e.g., the communication circuitry 291 of FIG. 2A, the communication circuitry 291 of FIG. 2B). According to an embodiment, the first external electronic device 202 may transmit/receive information to/from the wearable electronic device 201 and the second external electronic device 203 through the server 204 or transmit/receive information to/from the wearable electronic device 201 and the second external electronic device 203. For example, the first external electronic device 202 may be implemented as a wearable electronic device that may be worn on the user's body, a smartphone, a tablet PC, a computing device, or a TV. However, this is an example, and the first external electronic device 202 may be implemented as various devices. For example, the second external electronic device 203 may be implemented as a wearable electronic device that may be worn on the user's body, a smartphone, a tablet PC, a computing device, or a TV. However, this is an example, and the second external electronic device 203 may be implemented as various devices.

According to an embodiment, in operation 1711, the first external electronic device 202 may receive information indicating that the wearable electronic device 201 is not worn on the user's body while the wearable electronic device 201 executes at least one function.

According to an embodiment, in operation 1713, the first external electronic device 202 may identify the second external electronic device 203 that satisfies the specified condition. For example, the first external electronic device 202 may receive information about at least one external electronic device connected to the server 204 from the server 204. For example, the first external electronic device 202 may receive information about at least one external electronic device connected to the first external electronic device 202 from at least one external electronic device using a short-range communication technology. The first external electronic device 202 may identify the second external electronic device 203 that satisfies the specified condition based on the information about the at least one external electronic device.

According to an embodiment, in operation 1715, the first external electronic device 202 may provide a message to the second external electronic device 203 to display the information indicating that the second external electronic device 203 may execute at least one function. According to an embodiment, the second external electronic device 203 may provide a message requesting information for executing the first function to the first external electronic device 202 based on identifying a user input for executing the first function among the at least one function.

According to an embodiment, in operation 1717, the first external electronic device 202 may receive a message requesting information for executing the first function from the second external electronic device 203.

According to an embodiment, in operation 1719, the first external electronic device 202 may provide the information related to the first function to the second external electronic device 203 based on the message requesting information for executing the first function. According to an embodiment, the first external electronic device 202 may provide information indicating that the information related to the first function is provided to the second external electronic device 203 to the wearable electronic device 201. According to an embodiment, the second external electronic device 203 may continuously execute the first function based on the information related to the first function.

According to an embodiment, a wearable electronic device 201 may comprise a sensor 230, communication circuitry 290, at least one processor 220, and memory 210 storing instructions.

According to an embodiment, the instructions may be configured to, when executed by the at least one processor 220 individually or collectively, cause the wearable electronic device 201 to execute a first function of the wearable electronic device 201.

According to an embodiment, the instructions may be configured to, when executed by the at least one processor 220 individually or collectively, cause the wearable electronic device 201 to determine, through the sensor, that the wearable electronic device 201 is not worn on a user's body while executing the first function.

According to an embodiment, the instructions may be configured to, when executed by the at least one processor 220 individually or collectively, cause the wearable electronic device 201 to identify, through the communication circuitry, at least one external electronic device around the wearable electronic device 201.

According to an embodiment, the instructions may be configured to, when executed by the at least one processor 220 individually or collectively, cause the wearable electronic device 201 to based on identifying a first external electronic device 202, which satisfies a specified condition, among the at least one external electronic device, transmit, through the communication circuitry, a first command (e.g., the first message) configured to cause the first external electronic device 202 to display information indicating that a second function, corresponding to the first function, of the first external electronic device 202 is executable on the first external electronic device 202.

According to an embodiment, the instructions may be configured to, when executed by the at least one processor 220 individually or collectively, cause the wearable electronic device 201 to based on receiving, through the communication circuitry, a message requesting information for executing the second function, provide, to the first external electronic device 202, information related to the first function configured to cause the first external electronic device 202 to execute the second function using the information related to the first function.

According to an embodiment, the instructions may be configured to, when executed by the at least one processor 220 individually or collectively, cause the wearable electronic device 201 to identify the at least one external electronic device connected to the wearable electronic device 201 using a short-range communication scheme through the communication circuitry, or identify, through a server, the at least one external electronic device connected to the server using same information as authentication information specified for the wearable electronic device 201, or receive information indicating that the at least one external electronic device has been identified by a second external electronic device among the at least one external electronic device.

According to an embodiment, the instructions may be configured to, when executed by the at least one processor 220 individually or collectively, cause the wearable electronic device 201 to based on identifying that the first external electronic device 202 is in an activated state, identify that the first external electronic device 202 satisfies the specified condition. According to an embodiment, the activated state may include a state in which a display 202 of the first external electronic device is turned on or a state in which a battery level of a battery of the first external electronic device is higher than a specified level.

According to an embodiment, the instructions may be configured to, when executed by the at least one processor 220 individually or collectively, cause the wearable electronic device 201 to identify a number of user interactions input to each of the at least one external electronic device during a specified period.

According to an embodiment, the instructions may be configured to, when executed by the at least one processor 220 individually or collectively, cause the wearable electronic device 201 to based on identifying that the number of user interactions input to a specified external electronic device 202, among the at least one external electronic device, is the largest, identify that the first external electronic device 202 as the first external electronic device by determining that the specified external electronic device satisfied the specified condition.

According to an embodiment, the instructions may be configured to, when executed by the at least one processor 220 individually or collectively, cause the wearable electronic device 201 to based on determining that the first external electronic device 202 is worn on the user's body, identify that the first external electronic device 202 satisfies the specified condition.

According to an embodiment, the instructions may be configured to, when executed by the at least one processor 220 individually or collectively, cause the wearable electronic device 201 to transmit, through the communication circuitry, a second command (e.g., the first message) configured to cause the first external electronic device 202 to output a notification indicating that the first function is being executed on the wearable electronic device 201, to the first external electronic device.

According to an embodiment, the instructions may be configured to, when executed by the at least one processor 220 individually or collectively, cause the wearable electronic device 201 to identify whether the first function is executable on the first external electronic device 202.

According to an embodiment, the instructions may be configured to, when executed by the at least one processor 220 individually or collectively, cause the wearable electronic device 201 to, based on identifying that the first function is executable on the first external electronic device 202, transmit, through communication circuitry of the wearable device, a third command (e.g., the first message) configured to cause the first external electronic device 202 to display the information indicating that the second function of the first external electronic device 202 corresponding to the first function is executable on the first external electronic device 202.

According to an embodiment, the instructions may be configured to, when executed by the at least one processor 220 individually or collectively, cause the wearable electronic device 201 to, based on identifying that the first function is not executable on the first external electronic device 202, transmit, through the communication circuitry, a fourth command (e.g., a specified message) configured to cause a second external electronic device capable of executing the first function among the at least one external electronic device to display information indicating that a function of the first external electronic device 202 corresponding to the first function is executable on the second external electronic device, to the second external electronic device.

According to an embodiment, the instructions may be configured to, when executed by the at least one processor 220 individually or collectively, cause the wearable electronic device 201 to, based on identifying that a third function of the wearable electronic device 201 is executed on the wearable electronic device 201 within a specified time from a time when the first function is executed on the wearable electronic device 201, transmit, through the communication circuitry, a fifth command (e.g., the first message) configured to cause the first external electronic device 202 to display the second function corresponding to the first function and a fourth function of the first external electronic device 202 corresponding to the third function as one group, to the second external electronic device.

According to an embodiment, the instructions may be configured to, when executed by the at least one processor 220 individually or collectively, cause the wearable electronic device 201 to, based on history information related to at least one function stored in the wearable electronic device 201, transmit, through the communication circuitry, a sixth command (e.g., the first message) configured to cause the first external electronic device 202 to display information indicating that the second function of the first external electronic device 202 corresponding to the first function is executable on the first external electronic device 202, to the first external electronic device.

According to an embodiment, the instructions may be configured to, when executed by the at least one processor 220 individually or collectively, cause the wearable electronic device 201 to, based on providing the information related to the first function to the first external electronic device 202, terminate executing the first function.

According to an embodiment, the first function may include a function related to recording audio, a function related to a call, a function related to an exercise, a function related to a timer, a function related to playing content, or a function related to an output of a notification.

According to an embodiment, a method for operating a wearable electronic device 201 may comprise executing a first function of the wearable electronic device 201.

According to an embodiment, the method for operating the wearable electronic device 201 may comprise determining, through a sensor included in the wearable electronic device 201, that the wearable electronic device 201 is not worn on a user's body while executing the first function.

According to an embodiment, the method for operating the wearable electronic device 201 may comprise identifying, through communication circuitry included in the wearable electronic device 201, at least one external electronic device around the wearable electronic device 201.

According to an embodiment, the method for operating the wearable electronic device 201 may comprise, based on identifying a first external electronic device 202, which satisfies a specified condition, among the at least one external electronic device, transmitting, through the communication circuitry, a first command configured to cause the first external electronic device 202 to display information indicating that a second function, corresponding to the first function, of the first external electronic device 202 is executable on the first external electronic device 202.

According to an embodiment, the method for operating the wearable electronic device 201 may comprise, based on receiving, through the communication circuitry, a message requesting information for executing the second function, providing, to the first external electronic device 202, information related to the first function configured to cause the first external electronic device 202 to execute the second function using the information related to the first function.

According to an embodiment, the method for operating the wearable electronic device 201 may comprise identifying the at least one external electronic device connected to the wearable electronic device 201 using a short-range communication scheme through the communication circuitry, or identify, through a server, the at least one external electronic device connected to the server using same information as authentication information specified for the wearable electronic device 201, or receive information indicating that the at least one external electronic device has been identified by a second external electronic device among the at least one external electronic device.

According to an embodiment, the method for operating the wearable electronic device 201 may comprise, based on identifying that the first external electronic device 202 is in an activated state, identifying that the first external electronic device 202 satisfies the specified condition.

According to an embodiment, the method for operating the wearable electronic device 201 may comprise identifying a number of user interactions input to each of the at least one external electronic device during a specified period.

According to an embodiment, the method for operating the wearable electronic device 201 may comprise, based on identifying that the number of user interactions input to the specified external electronic device 202, among the at least one external electronic device, is the largest, identifying that the specified external electronic device 202 as the first external electronic device by determining that the specified external electronic device satisfied the specified condition.

According to an embodiment, the method for operating the wearable electronic device 201 may comprise, based on determining that the first external electronic device 202 is worn on the user's body, identifying that the first external electronic device 202 satisfies the specified condition.

According to an embodiment, the method for operating the wearable electronic device 201 may comprise transmitting, through the communication circuitry, a second command configured to output, through the first external electronic device, a notification indicating that the first function is being executed on the wearable electronic device 201, to the first external electronic device.

According to an embodiment, the method for operating the wearable electronic device 201 may comprise, based on identifying that the first function is executable on the first external electronic device 202, transmitting, through the communication circuitry, a third command configured to cause the first external electronic device 202 to display the information indicating that the second function of the first external electronic device 202 corresponding to the first function is executable on the first external electronic device 202, to the first external electronic device.

According to an embodiment, in a non-transitory storage medium storing computer-readable instructions, the instructions may, when executed by at least one processor 220 of a wearable electronic device 201, cause the wearable electronic device 201 to perform at least one operation. The at least one operation may comprise executing a first function of the wearable electronic device 201.

According to an embodiment, in the non-transitory storage medium storing computer-readable instructions, the instructions may, when executed by the at least one processor 220 of the wearable electronic device 201, cause the wearable electronic device 201 to perform at least one operation. The at least one operation may comprise determining, through a sensor included in the wearable electronic device 201, that the wearable electronic device 201 is not worn on a user's body while executing the first function.

According to an embodiment, in the non-transitory storage medium storing computer-readable instructions, the instructions may, when executed by the at least one processor 220 of the wearable electronic device 201, cause the wearable electronic device 201 to perform at least one operation. The at least one operation may comprise identifying, through communication circuitry included in the wearable electronic device 201, at least one external electronic device around the wearable electronic device 201.

According to an embodiment, in the non-transitory storage medium storing computer-readable instructions, the instructions may, when executed by the at least one processor 220 of the wearable electronic device 201, cause the wearable electronic device 201 to perform at least one operation. The at least one operation may comprise based on identifying a first external electronic device 202, which satisfies a specified condition, among the at least one external electronic device, transmitting, through communication circuitry of the wearable device, a first command configured to cause the first external electronic device 202 to display information indicating that a second function, corresponding to the first function, of the first external electronic device 202 is executable on the first external electronic device 202.

According to an embodiment, in the non-transitory storage medium storing computer-readable instructions, the instructions may, when executed by the at least one processor 220 of the wearable electronic device 201, cause the wearable electronic device 201 to perform at least one operation. The at least one operation may comprise, based on receiving, through the communication circuitry, a message requesting information for executing the second function from the first external electronic device 202, providing, to the first external electronic device 202, information related to the first function configured to cause the first external electronic device 202 executes the second function using the information related to the first function.

The electronic device according to various embodiments may be one of various types of electronic devices. The electronic devices may include, for example, a portable communication device (e.g., a smartphone), a computer device, a portable multimedia device, a portable medical device, a camera, a wearable device, or a home appliance. According to an embodiment of the disclosure, the electronic device is not limited to the above-listed embodiments.

It should be appreciated that various embodiments of the disclosure and the terms used therein are not intended to limit the technological features set forth herein to particular embodiments and include various changes, equivalents, or replacements for a corresponding embodiment. With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), it means that the element may be coupled with the other element directly (e.g., wiredly), wirelessly, or via a third element.

As used herein, the term “module” may include a unit implemented in hardware, software, or firmware, and may interchangeably be used with other terms, for example, “logic,” “logic block,” “part,” or “circuitry”. A module may be a single integral component, or a minimum unit or part thereof, adapted to perform one or more functions. For example, according to an embodiment, the module may be implemented in a form of an application-specific integrated circuit (ASIC).

Various embodiments as set forth herein may be implemented as software (e.g., the program 140) including one or more instructions that are stored in a storage medium (e.g., internal memory 136 or external memory 138) that is readable by a machine (e.g., the electronic device 101, 201, 202, or 203). For example, a processor (e.g., the processor 120, 220, 221, or 222) of the machine (e.g., the electronic device 101, 201, 202, or 203) may invoke at least one of the one or more instructions stored in the storage medium, and execute it, with or without using one or more other components under the control of the processor. This allows the machine to be operated to perform at least one function according to the at least one instruction invoked. The one or more instructions may include a code generated by a complier or a code executable by an interpreter. The storage medium readable by the machine may be provided in the form of a non-transitory storage medium. Wherein, the term “non-transitory” simply means that the storage medium is a tangible device, and does not include a signal (e.g., an electromagnetic wave), but this term does not differentiate between where data is semi-permanently stored in the storage medium and where the data is temporarily stored in the storage medium.

According to an embodiment, a method according to various embodiments of the disclosure may be included and provided in a computer program product. The computer program products may be traded as commodities between sellers and buyers. The computer program product may be distributed in the form of a machine-readable storage medium (e.g., compact disc read only memory (CD-ROM)), or be distributed (e.g., downloaded or uploaded) online via an application store (e.g., Play Store™), or between two user devices (e.g., smart phones) directly. If distributed online, at least part of the computer program product may be temporarily generated or at least temporarily stored in the machine-readable storage medium, such as memory of the manufacturer's server, a server of the application store, or a relay server.

According to various embodiments, each component (e.g., a module or a program) of the above-described components may include a single entity or multiple entities. Some of the plurality of entities may be separately disposed in different components. According to various embodiments, one or more of the above-described components may be omitted, or one or more other components may be added. Alternatively or additionally, a plurality of components (e.g., modules or programs) may be integrated into a single component. In such a case, according to various embodiments, the integrated component may still perform one or more functions of each of the plurality of components in the same or similar manner as they are performed by a corresponding one of the plurality of components before the integration. According to various embodiments, operations performed by the module, the program, or another component may be carried out sequentially, in parallel, repeatedly, or heuristically, or one or more of the operations may be executed in a different order or omitted, or one or more other operations may be added.

1. A wearable electronic device comprising:
a sensor;
communication circuitry;
at least one processor, and
memory storing instructions that, when executed by the at least one processor individually or collectively, cause the wearable electronic device to:
execute a first function of the wearable electronic device,
determine, through the sensor, that the wearable electronic device is not worn on a user's body while executing the first function,
identify, through the communication circuitry, at least one external electronic device around the wearable electronic device,
based on identifying a first external electronic device, which satisfies a specified condition, among the at least one external electronic device, transmit, through the communication circuitry, a first command configured to cause the first external electronic device to display information indicating that a second function, corresponding to the first function, of the first external electronic device is executable on the first external electronic device, and
based on receiving, through the communication circuitry, a message requesting information for executing the second function, provide, to the first external electronic device, information related to the first function configured to cause the first external electronic device to execute the second function using the information related to the first function.

2. The wearable electronic device of claim 1, wherein the instructions, when executed by the at least one processor individually or collectively, further cause the wearable electronic device to:
identify the at least one external electronic device connected to the wearable electronic device using short-range communication scheme through the communication circuitry, or identify, through a server, the at least one external electronic device connected to the server using information that is same as authentication information specified for the wearable electronic device, or
receive information indicating that the at least one external electronic device has been identified by a second external electronic device among the at least one external electronic device.

3. The wearable electronic device of claim 1, wherein the instructions, when executed by the at least one processor individually or collectively, further cause the wearable electronic device to:
based on identifying that the first external electronic device is in an activated state, identify that the first external electronic device satisfies the specified condition,
wherein the activated state includes a state in which a display of the first external electronic device is turned on or a state in which a battery level of a battery of the first external electronic device is higher than a specified level.

4. The wearable electronic device of claim 1, wherein the instructions, when executed by the at least one processor individually or collectively, further cause the wearable electronic device to:
identify numbers of user interactions input to the at least one external electronic device during a specified period, and
based on identifying that a number of user interactions input to a specified external electronic device, among the at least one external electronic device, is the largest among the numbers of user interactions input to the at least one external electronic device, determine that the specified external electronic device as the first external electronic device by determining that the specified external electronic device satisfied the specified condition.

5. The wearable electronic device of claim 1, wherein the instructions, when executed by the at least one processor individually or collectively, further cause the wearable electronic device to:
based on determining that the first external electronic device is worn on the user's body, identify that the first external electronic device satisfies the specified condition.

6. The wearable electronic device of claim 1, wherein the instructions, when executed by the at least one processor individually or collectively, further cause the wearable electronic device to:
transmit, through the communication circuitry, a second command configured to cause the first external electronic device to output a notification indicating that the first function is being executed on the wearable electronic device, to the first external electronic device.

7. The wearable electronic device of claim 1, wherein the instructions, when executed by the at least one processor individually or collectively, further cause the wearable electronic device to:
identify whether the first function is executable on the first external electronic device, and
based on identifying that the first function is executable on the first external electronic device, transmit, through communication circuitry of the wearable device, a third command configured to cause the first external electronic device to display the information indicating that the second function of the first external electronic device corresponding to the first function is executable on the first external electronic device, to the first external electronic device.

8. The wearable electronic device of claim 1, wherein the instructions, when executed by the at least one processor individually or collectively, further cause the wearable electronic device to:
based on identifying that the first function is not executable on the first external electronic device, transmit, through the communication circuitry, a fourth command configured to cause a second external electronic device capable of executing the first function among the at least one external electronic device to display information indicating that a function of the first external electronic device corresponding to the first function is executable on the second external electronic device, to the second external electronic device.

9. The wearable electronic device of claim 1, wherein the instructions, when executed by the at least one processor individually or collectively, further cause the wearable electronic device to:
based on identifying that a third function of the wearable electronic device is executed on the wearable electronic device within a specified time from a time when the first function is executed on the wearable electronic device, transmit, through the communication circuitry, a fifth command configured to cause the first external electronic device to display the second function corresponding to the first function and a fourth function of the first external electronic device corresponding to the third function as one group, to the first external electronic device.

10. The wearable electronic device of claim 1, wherein the instructions, when executed by the at least one processor individually or collectively, further cause the wearable electronic device to:
based on history information related to at least one function stored in the wearable electronic device, transmit, through the communication circuitry, a sixth command configured to cause the first external electronic device to display information indicating that the second function of the first external electronic device corresponding to the first function is executable on the first external electronic device, to the first external electronic device.

11. The wearable electronic device of claim 1, wherein the instructions, when executed by the at least one processor individually or collectively, further cause the wearable electronic device to:
based on providing the information related to the first function to the first external electronic device, terminate executing the first function.

12. The wearable electronic device of claim 1, wherein the first function includes a function related to recording audio, a function related to a call, a function related to an exercise, a function related to a timer, a function related to playing content, or a function related to an output of a notification.

13. A method for operating a wearable electronic device, the method comprising:
executing a first function of the wearable electronic device;
determining, through a sensor included in the wearable electronic device, that the wearable electronic device is not worn on a user's body while executing the first function;
identifying, through communication circuitry included in the wearable electronic device, at least one external electronic device around the wearable electronic device;
based on identifying a first external electronic device, which satisfies a specified condition, among the at least one external electronic device, transmitting, through the communication circuitry, a first command configured to cause the first external electronic device to display information indicating that a second function, corresponding to the first function, of the first external electronic device is executable on the first external electronic device; and
based on receiving, through the communication circuitry, a message requesting information for executing the second function, providing, to the first external electronic device, information related to the first function configured to cause the first external electronic device to execute the second function using the information related to the first function.

14. The method of claim 13, further comprising identifying the at least one external electronic device around the wearable electronic device using a short-range communication scheme through the communication circuitry, or identifying, through a server, the at least one external electronic device connected to the server using information that is same as authentication information specified for the wearable electronic device, or receiving information indicating that the at least one external electronic device has been identified by a second external electronic device among the at least one external electronic device.

15. The method of claim 13, wherein identifying the first external electronic device satisfying the specified conditions includes, based on identifying that the first external electronic device is in an activated state, identifying that the first external electronic device satisfies the specified condition, and
wherein the activated state includes a state in which a display of the first external electronic device is turned on or a state in which a battery level of a battery of the first external electronic device is higher than a specified level.
